(19) United States
(12) Patent Application Publication
(10) Pub. No.: US 2025/0286578 A1
(43) Pub. Date: Sep. 11, 2025

(54) NON-TERRESTRIAL NETWORK COMMUNICATION AND POSITIONING FREQUENCY BAND RECEPTION

(71) Applicant: QUALCOMM Incorporated, San Diego, CA (US)

(72) Inventors: Fnu SIDDHANT, Bangalore (IN); Mukesh KUMAR, Hyderabad (IN); Yogendra Umesh ITANKAR, Hyderabad (IN); Jordan COOKMAN, San Jose, CA (US)

(21) Appl. No.: 18/600,505

(22) Filed: Mar. 8, 2024

(51) Int. Cl. H04B 1/403; H03M 1/12; H04W 84/06

(52) U.S. Cl. CPC H04B 1/403; H03M 1/1245; H04W 84/06

(57) ABSTRACT

Disclosed are techniques for wireless communication. In an aspect, a user equipment (UE) may receive a first signal from a communication source and a second signal from a positioning satellite source different from the communication source using a radio frequency front end (RFFE) circuit block. The UE may store first analog-to-digital converter (ADC) samples corresponding to the first signal and second ADC samples corresponding to the second signal.

### BACKGROUND OF THE DISCLOSURE

### 1. Field of the Disclosure

Aspects of the disclosure relate generally to wireless technologies.

### 2. Description of the Related Art

Wireless communication systems have developed through various generations, including a first-generation analog wireless phone service (1G), a second-generation (2G) digital wireless phone service (including interim 2.5G and 2.75G networks), a third-generation (3G) high speed data, Internet-capable wireless service and a fourth-generation (4G) service (e.g., Long Term Evolution (LTE) or WiMax). There are presently many different types of wireless communication systems in use, including cellular and personal communications service (PCS) systems. Examples of known cellular systems include the cellular analog advanced mobile phone system (AMPS), and digital cellular systems based on code division multiple access (CDMA), frequency division multiple access (FDMA), time division multiple access (TDMA), the Global System for Mobile communications (GSM), etc.

A fifth generation (5G) wireless standard, referred to as New Radio (NR), enables higher data transfer speeds, greater numbers of connections, and better coverage, among other improvements. The 5G standard, according to the Next Generation Mobile Networks Alliance, is designed to provide higher data rates as compared to previous standards, more accurate positioning (e.g., based on reference signals for positioning (RS-P), such as downlink, uplink, or sidelink positioning reference signals (PRS)), and other technical enhancements. These enhancements, as well as the use of higher frequency bands, advances in PRS processes and technology, and high-density deployments for 5G, enable highly accurate 5G-based positioning.

### SUMMARY

The following presents a simplified summary relating to one or more aspects disclosed herein. Thus, the following summary should not be considered an extensive overview relating to all contemplated aspects, nor should the following summary be considered to identify key or critical elements relating to all contemplated aspects or to delineate the scope associated with any particular aspect. Accordingly, the following summary has the sole purpose to present certain concepts relating to one or more aspects relating to the mechanisms disclosed herein in a simplified form to precede the detailed description presented below.

In an aspect, a method of wireless communication performed by a user equipment (UE) includes receiving a first signal from a communication source and a second signal from a positioning satellite source different from the communication source using a radio frequency front end (RFFE) circuit block; and storing first analog-to-digital converter (ADC) samples corresponding to the first signal and second ADC samples corresponding to the second signal.

In some aspects, the RFFE circuit block comprises: an RFFE circuit having a local oscillator (LO) configured to a radio frequency between a first frequency range associated with the first signal and a second frequency range associated with the second signal; and a wideband ADC circuit having a sampling clock configured to sample the first frequency range and the second frequency range.

In some aspects, the method includes processing the stored first ADC samples using a first digital front end (DFE) circuit block; and processing the stored second ADC samples using a second DFE circuit block different from the first DFE circuit block.

In some aspects, the method includes configuring one or more components of a digital front end (DFE) circuit block with a first software configuration for use during a first time period; processing the stored first ADC samples using the DFE circuit block during the first time period; configuring the one or more components of the DFE circuit block with a second software configuration different from the first software configuration for use during a second time period different from the first time period; and processing the stored second ADC samples using the DFE circuit block during the second time period.

In some aspects, the RFFE circuit block is a circuit block that is common with the DFE circuit block, and an ADC sampling reference clock operates continuously during a time period when the second signal from the positioning satellite source is received until post-processing of the stored second ADC samples is completed.

In some aspects, the method includes processing the stored second ADC samples using a digital front end (DFE) circuit block; performing a post-processing operation on the processed second ADC samples, wherein the post-processing operation includes a coherent integration process, a non-coherent integration process, or both; and determining a single shot position fix based on the performed post-processing operation.

In some aspects, the DFE circuit block includes: an intermediate frequency (IF) down conversion circuit, a decimation circuit, or any combination thereof.

In some aspects, the method includes scheduling the stored second ADC samples for processing using the DFE circuit block during a measurement gap, a connected mode discontinuous reception (DRX) off period, an idle mode DRX off period, or any combination thereof.

In some aspects, the method includes starting a discard timer when the second ADC samples are stored in one or more memories; and discarding the stored second ADC samples based on an expiration of the discard timer occurring prior to processing the stored second ADC samples.

In some aspects, the method includes receiving an updated navigation message; and discarding the stored second ADC samples based on receiving the updated navigation message.

In some aspects, the method includes receiving an indication that a reception of the second signal from the positioning satellite source is scheduled for a first time period different from a second time period at which an uplink transmission is scheduled.

In some aspects, the communication source corresponds to a non-terrestrial network (NTN) satellite, or the positioning satellite source corresponds to a global navigation satellite system (GNSS) satellite, or the first signal corresponds to an NTN n255 downlink frequency band, or the second signal corresponds to a GNSS L1 frequency band, or any combination thereof.

In an aspect, a user equipment (UE) includes one or more memories; one or more transceivers; and one or more processors communicatively coupled to the one or more memories and the one or more transceivers, the one or more processors, either alone or in combination, configured to: receive, via the one or more transceivers, a first signal from a communication source and a second signal from a positioning satellite source different from the communication source using a radio frequency front end (RFFE) circuit block; and store first analog-to-digital converter (ADC) samples corresponding to the first signal and second ADC samples corresponding to the second signal.

In an aspect, a user equipment (UE) includes means for receiving a first signal from a communication source and a second signal from a positioning satellite source different from the communication source using a radio frequency front end (RFFE) circuit block; and means for storing first analog-to-digital converter (ADC) samples corresponding to the first signal and second ADC samples corresponding to the second signal.

In an aspect, a non-transitory computer-readable medium stores computer-executable instructions that, when executed by a user equipment (UE), cause the UE to: receive a first signal from a communication source and a second signal from a positioning satellite source different from the communication source using a radio frequency front end (RFFE) circuit block; and store first analog-to-digital converter (ADC) samples corresponding to the first signal and second ADC samples corresponding to the second signal.

In an aspect, an apparatus includes a radio frequency front end (RFFE) circuit configured to receive a first signal and a second signal different from the first signal communication source, the RFFE circuit having a local oscillator (LO) configured to a radio frequency between a first frequency range associated with the first signal and a second frequency range associated with the second signal; a wideband analog-to-digital converter (ADC) circuit operably coupled to the RFFE circuit, the wideband ADC circuit having a sampling clock configured to sample the first frequency range and the second frequency range; and one or more memories configured to store first ADC samples corresponding to the first signal and second ADC samples corresponding to the second signal.

Other objects and advantages associated with the aspects disclosed herein will be apparent to those skilled in the art based on the accompanying drawings and detailed description.

### BRIEF DESCRIPTION OF THE DRAWINGS

The accompanying drawings are presented to aid in the description of various aspects of the disclosure and are provided solely for illustration of the aspects and not limitation thereof.

FIG. 1 illustrates an example wireless communications system, according to aspects of the disclosure.

FIGS. 2A and 2B illustrate example wireless network structures, according to aspects of the disclosure.

FIG. 3 illustrates an example user equipment (UE) architecture, according to aspects of the disclosure.

FIG. 4 illustrates example Long-Term Evolution (LTE) positioning protocol (LPP) reference sources for positioning, according to aspects of the disclosure.

FIG. 5 illustrates an example non-terrestrial network (NTN) system with satellite sources for communication and positioning, according to aspects of the disclosure.

FIG. 6 illustrates an example frequency range diagram for reception of communication and positioning signals, according to aspects of the disclosure.

FIG. 7 illustrates an example timing diagram for time-shared processing of communication and positioning signals, according to aspects of the disclosure.

FIG. 8 illustrates a first block diagram of example common modem hardware resources that may support NTN communication and positioning frequency band reception and time-shared processing, according to aspects of the disclosure.

FIG. 9 illustrates a second block diagram of example common modem hardware resources that may support NTN communication and positioning frequency band reception and time-shared processing, according to aspects of the disclosure.

FIG. 10 illustrates a first timing diagram of an example positioning signal processing, according to aspects of the disclosure.

FIG. 11 illustrates a second timing diagram of an example positioning signal processing, according to aspects of the disclosure.

FIG. 12 illustrates an example simulation results signal plot corresponding to NTN communication and positioning frequency band reception and time-shared processing using common modem hardware resources, according to aspects of the disclosure.

FIG. 13 illustrates an example simulation results energy grid corresponding to NTN communication and positioning frequency band reception and time-shared processing using common modem hardware resources, according to aspects of the disclosure.

FIG. 14 illustrates an example process of wireless communication, according to aspects of the disclosure.

### DETAILED DESCRIPTION

Aspects of the disclosure are provided in the following description and related drawings directed to various examples provided for illustration purposes. Alternate aspects may be devised without departing from the scope of the disclosure. Additionally, well-known elements of the disclosure will not be described in detail or will be omitted so as not to obscure the relevant details of the disclosure.

Various aspects relate generally to reception of signals from multiple frequency bands using common modem hardware resources and processing the received signals using time sharing techniques. Some aspects more specifically relate to receiving (concurrently or otherwise) a first signal from a communication source and a second signal from positioning satellite source. For example, the communication source may be a non-terrestrial network (NTN) aerial base station/satellite and the positioning satellite source may be a global navigation satellite system (GNSS) satellite. That is, for example, a user equipment (UE) may concurrently receive the first signal associated with an NTN frequency band from the NTN satellite and the second signal associated with a GNSS frequency band from the GNSS satellite using a common radio frequency front end (RFFE) circuit block.

Additionally, or alternatively, time-sharing techniques may be used to process the received first and second signals. In some cases, analog-to-digital converter (ADC) samples corresponding to the received first and second signals may be stored and processed using a common first digital front end (DFE) circuit block in accordance with time-sharing techniques.

Particular aspects of the subject matter described in this disclosure can be implemented to realize one or more of the following potential advantages. In some examples, by using at least some common modem hardware resources to receive (e.g., concurrently receive in some cases) and/or process communication signals and GNSS signals, efficient GNSS-based positioning services may be enabled in a low-cost UE, such as an Internet of Things (IoT) device.

The words “exemplary” and/or “example” are used herein to mean “serving as an example, instance, or illustration.” Any aspect described herein as “exemplary” and/or “example” is not necessarily to be construed as preferred or advantageous over other aspects. Likewise, the term “aspects of the disclosure” does not require that all aspects of the disclosure include the discussed feature, advantage or mode of operation.

Those of skill in the art will appreciate that the information and signals described below may be represented using any of a variety of different technologies and techniques. For example, data, instructions, commands, information, signals, bits, symbols, and chips that may be referenced throughout the description below may be represented by voltages, currents, electromagnetic waves, magnetic fields or particles, optical fields or particles, or any combination thereof, depending in part on the particular application, in part on the desired design, in part on the corresponding technology, etc.

Further, many aspects are described in terms of sequences of actions to be performed by, for example, elements of a computing device. It will be recognized that various actions described herein can be performed by specific circuits (e.g., application specific integrated circuits (ASICs)), by program instructions being executed by one or more processors, or by a combination of both. Additionally, the sequence(s) of actions described herein can be considered to be embodied entirely within any form of non-transitory computer-readable storage medium having stored therein a corresponding set of computer instructions that, upon execution, would cause or instruct an associated processor of a device to perform the functionality described herein. Thus, the various aspects of the disclosure may be embodied in a number of different forms, all of which have been contemplated to be within the scope of the claimed subject matter. In addition, for each of the aspects described herein, the corresponding form of any such aspects may be described herein as, for example, “logic configured to” perform the described action.

As used herein, the terms “user equipment” (UE) and “base station” are not intended to be specific or otherwise limited to any particular radio access technology (RAT), unless otherwise noted. In general, a UE may be any wireless communication device (e.g., a mobile phone, router, tablet computer, laptop computer, consumer asset locating device, wearable (e.g., smartwatch, glasses, augmented reality (AR)/virtual reality (VR) headset, etc.), vehicle (e.g., automobile, motorcycle, bicycle, etc.), IoT device, etc.) used by a user to communicate over a wireless communications network. A UE may be mobile or may (e.g., at certain times) be stationary, and may communicate with a radio access network (RAN). As used herein, the term “UE” may be referred to interchangeably as an “access terminal” or “AT,” a “client device,” a “wireless device,” a “subscriber device,” a “subscriber terminal,” a “subscriber station,” a “user terminal” or “UT,” a “mobile device,” a “mobile terminal,” a “mobile station,” or variations thereof. Generally, UEs can communicate with a core network via a RAN, and through the core network the UEs can be connected with external networks such as the Internet and with other UEs. Of course, other mechanisms of connecting to the core network and/or the Internet are also possible for the UEs, such as over wired access networks, wireless local area network (WLAN) networks (e.g., based on the Institute of Electrical and Electronics Engineers (IEEE) 802.11 specification, etc.) and so on.

A base station may operate according to one of several RATs in communication with UEs depending on the network in which it is deployed, and may be alternatively referred to as an access point (AP), a network node, a NodeB, an evolved NodeB (eNB), a next generation eNB (ng-eNB), a New Radio (NR) Node B (also referred to as a gNB or gNodeB), etc. A base station may be used primarily to support wireless access by UEs, including supporting data, voice, and/or signaling connections for the supported UEs. In some systems a base station may provide purely edge node signaling functions while in other systems it may provide additional control and/or network management functions. A communication link through which UEs can send signals to a base station is called an uplink (UL) channel (e.g., a reverse traffic channel, a reverse control channel, an access channel, etc.). A communication link through which the base station can send signals to UEs is called a downlink (DL) or forward link channel (e.g., a paging channel, a control channel, a broadcast channel, a forward traffic channel, etc.). As used herein the term traffic channel (TCH) can refer to either an uplink/reverse or downlink/forward traffic channel.

The term “base station” may refer to a single physical transmission-reception point (TRP) or to multiple physical TRPs that may or may not be co-located. For example, where the term “base station” refers to a single physical TRP, the physical TRP may be an antenna of the base station corresponding to a cell (or several cell sectors) of the base station. Where the term “base station” refers to multiple co-located physical TRPs, the physical TRPs may be an array of antennas (e.g., as in a multiple-input multiple-output (MIMO) system or where the base station employs beamforming) of the base station. Where the term “base station” refers to multiple non-co-located physical TRPs, the physical TRPs may be a distributed antenna system (DAS) (a network of spatially separated antennas connected to a common source via a transport medium) or a remote radio head (RRH) (a remote base station connected to a serving base station). Alternatively, the non-co-located physical TRPs may be the serving base station receiving the measurement report from the UE and a neighbor base station whose reference radio frequency (RF) signals the UE is measuring. Because a TRP is the point from which a base station transmits and receives wireless signals, as used herein, references to transmission from or reception at a base station are to be understood as referring to a particular TRP of the base station.

In some implementations that support positioning of UEs, a base station may not support wireless access by UEs (e.g., may not support data, voice, and/or signaling connections for UEs), but may instead transmit reference signals to UEs to be measured by the UEs, and/or may receive and measure signals transmitted by the UEs. Such a base station may be referred to as a positioning beacon (e.g., when transmitting signals to UEs) and/or as a location measurement unit (e.g., when receiving and measuring signals from UEs).

An “RF signal” comprises an electromagnetic wave of a given frequency that transports information through the space between a transmitter and a receiver. As used herein, a transmitter may transmit a single “RF signal” or multiple “RF signals” to a receiver. However, the receiver may receive multiple “RF signals” corresponding to each transmitted RF signal due to the propagation characteristics of RF signals through multipath channels. The same transmitted RF signal on different paths between the transmitter and receiver may be referred to as a “multipath” RF signal. As used herein, an RF signal may also be referred to as a “wireless signal” or simply a “signal” where it is clear from the context that the term “signal” refers to a wireless signal or an RF signal.

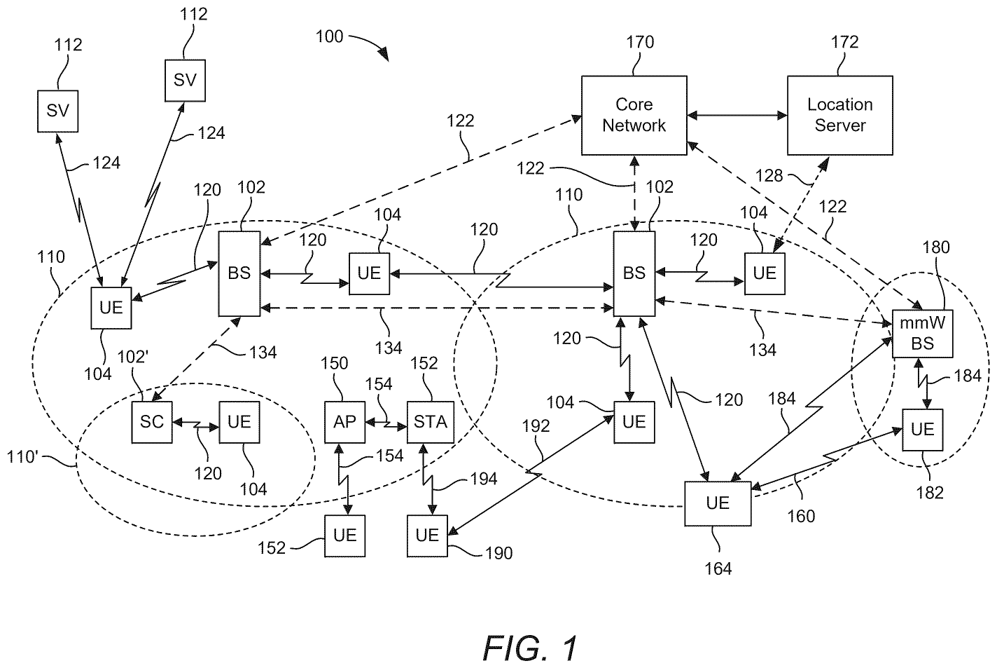

FIG. 1 illustrates an example wireless communications system 100, according to aspects of the disclosure. The wireless communications system 100 (which may also be referred to as a wireless wide area network (WWAN)) may include various base stations 102 (labeled “BS”) and various UEs 104. The base stations 102 may include macro cell base stations (high power cellular base stations) and/or small cell base stations (low power cellular base stations). In an aspect, the macro cell base stations may include eNBs and/or ng-eNBs where the wireless communications system 100 corresponds to an LTE network, or gNBs where the wireless communications system 100 corresponds to a NR network, or a combination of both, and the small cell base stations may include femtocells, picocells, microcells, etc.

The base stations 102 may collectively form a RAN and interface with a core network 170 (e.g., an evolved packet core (EPC) or a 5G core (5GC)) through backhaul links 122, and through the core network 170 to one or more location servers 172 (e.g., a location management function (LMF) or a secure user plane location (SUPL) location platform (SLP)). The location server(s) 172 may be part of core network 170 or may be external to core network 170. A location server 172 may be integrated with a base station 102. A UE 104 may communicate with a location server 172 directly or indirectly. For example, a UE 104 may communicate with a location server 172 via the base station 102 that is currently serving that UE 104. A UE 104 may also communicate with a location server 172 through another path, such as via an application server (not shown), via another network, such as via a wireless local area network (WLAN) access point (AP) (e.g., AP 150 described below), and so on. For signaling purposes, communication between a UE 104 and a location server 172 may be represented as an indirect connection (e.g., through the core network 170, etc.) or a direct connection (e.g., as shown via direct connection 128), with the intervening nodes (if any) omitted from a signaling diagram for clarity.

In addition to other functions, the base stations 102 may perform functions that relate to one or more of transferring user data, radio channel ciphering and deciphering, integrity protection, header compression, mobility control functions (e.g., handover, dual connectivity), inter-cell interference coordination, connection setup and release, load balancing, distribution for non-access stratum (NAS) messages, NAS node selection, synchronization, RAN sharing, multimedia broadcast multicast service (MBMS), subscriber and equipment trace, RAN information management (RIM), paging, positioning, and delivery of warning messages. The base stations 102 may communicate with each other directly or indirectly (e.g., through the EPC/5GC) over backhaul links 134, which may be wired or wireless.

The base stations 102 may wirelessly communicate with the UEs 104. Each of the base stations 102 may provide communication coverage for a respective geographic coverage area 110. In an aspect, one or more cells may be supported by a base station 102 in each geographic coverage area 110. A “cell” is a logical communication entity used for communication with a base station (e.g., over some frequency resource, referred to as a carrier frequency, component carrier, carrier, band, or the like), and may be associated with an identifier (e.g., a physical cell identifier (PCI), an enhanced cell identifier (ECI), a virtual cell identifier (VCI), a cell global identifier (CGI), etc.) for distinguishing cells operating via the same or a different carrier frequency. In some cases, different cells may be configured according to different protocol types (e.g., machine-type communication (MTC), narrowband IoT (NB-IoT), enhanced mobile broadband (eMBB), or others) that may provide access for different types of UEs. Because a cell is supported by a specific base station, the term “cell” may refer to either or both of the logical communication entity and the base station that supports it, depending on the context. In addition, because a TRP is typically the physical transmission point of a cell, the terms “cell” and “TRP” may be used interchangeably. In some cases, the term “cell” may also refer to a geographic coverage area of a base station (e.g., a sector), insofar as a carrier frequency can be detected and used for communication within some portion of geographic coverage areas 110.

While neighboring macro cell base station 102 geographic coverage areas 110 may partially overlap (e.g., in a handover region), some of the geographic coverage areas 110 may be substantially overlapped by a larger geographic coverage area 110. For example, a small cell base station 102′ (labeled “SC” for “small cell”) may have a geographic coverage area 110′ that substantially overlaps with the geographic coverage area 110 of one or more macro cell base stations 102. A network that includes both small cell and macro cell base stations may be known as a heterogeneous network. A heterogeneous network may also include home eNBs (HeNBs), which may provide service to a restricted group known as a closed subscriber group (CSG).

The communication links 120 between the base stations 102 and the UEs 104 may include uplink (also referred to as reverse link) transmissions from a UE 104 to a base station 102 and/or downlink (DL) (also referred to as forward link) transmissions from a base station 102 to a UE 104. The communication links 120 may use MIMO antenna technology, including spatial multiplexing, beamforming, and/or transmit diversity. The communication links 120 may be through one or more carrier frequencies. Allocation of carriers may be asymmetric with respect to downlink and uplink (e.g., more or less carriers may be allocated for downlink than for uplink).

The wireless communications system 100 may further include a wireless local area network (WLAN) access point (AP) 150 in communication with WLAN stations (STAs) 152 via communication links 154 in an unlicensed frequency spectrum (e.g., 5 GHz). When communicating in an unlicensed frequency spectrum, the WLAN STAs 152 and/or the WLAN AP 150 may perform a clear channel assessment (CCA) or listen before talk (LBT) procedure prior to communicating in order to determine whether the channel is available.

The small cell base station 102′ may operate in a licensed and/or an unlicensed frequency spectrum. When operating in an unlicensed frequency spectrum, the small cell base station 102′ may employ LTE or NR technology and use the same 5 GHz unlicensed frequency spectrum as used by the WLAN AP 150. The small cell base station 102′, employing LTE/5G in an unlicensed frequency spectrum, may boost coverage to and/or increase capacity of the access network. NR in unlicensed spectrum may be referred to as NR-U. LTE in an unlicensed spectrum may be referred to as LTE-U, licensed assisted access (LAA), or MULTEFIRE®.

The wireless communications system 100 may further include a millimeter wave (mmW) base station 180 that may operate in mmW frequencies and/or near mmW frequencies in communication with a UE 182. Extremely high frequency (EHF) is part of the RF in the electromagnetic spectrum. EHF has a range of 30 GHz to 300 GHz and a wavelength between 1 millimeter and 10 millimeters. Radio waves in this band may be referred to as a millimeter wave. Near mmW may extend down to a frequency of 3 GHz with a wavelength of 100 millimeters. The super high frequency (SHF) band extends between 3 GHz and 30 GHz, also referred to as centimeter wave. Communications using the mmW/near mmW radio frequency band have high path loss and a relatively short range. The mmW base station 180 and the UE 182 may utilize beamforming (transmit and/or receive) over a mmW communication link 184 to compensate for the extremely high path loss and short range. Further, it will be appreciated that in alternative configurations, one or more base stations 102 may also transmit using mmW or near mmW and beamforming. Accordingly, it will be appreciated that the foregoing illustrations are merely examples and should not be construed to limit the various aspects disclosed herein.

Transmit beamforming is a technique for focusing an RF signal in a specific direction. Traditionally, when a network node (e.g., a base station) broadcasts an RF signal, it broadcasts the signal in all directions (omni-directionally). With transmit beamforming, the network node determines where a given target device (e.g., a UE) is located (relative to the transmitting network node) and projects a stronger downlink RF signal in that specific direction, thereby providing a faster (in terms of data rate) and stronger RF signal for the receiving device(s). To change the directionality of the RF signal when transmitting, a network node can control the phase and relative amplitude of the RF signal at each of the one or more transmitters that are broadcasting the RF signal. For example, a network node may use an array of antennas (referred to as a “phased array” or an “antenna array”) that creates a beam of RF waves that can be “steered” to point in different directions, without actually moving the antennas. Specifically, the RF current from the transmitter is fed to the individual antennas with the correct phase relationship so that the radio waves from the separate antennas add together to increase the radiation in a desired direction, while cancelling to suppress radiation in undesired directions.

Transmit beams may be quasi-co-located, meaning that they appear to the receiver (e.g., a UE) as having the same parameters, regardless of whether or not the transmitting antennas of the network node themselves are physically co-located. In NR, there are four types of quasi-co-location (QCL) relations. Specifically, a QCL relation of a given type means that certain parameters about a second reference RF signal on a second beam can be derived from information about a source reference RF signal on a source beam. Thus, if the source reference RF signal is QCL Type A, the receiver can use the source reference RF signal to estimate the Doppler shift, Doppler spread, average delay, and delay spread of a second reference RF signal transmitted on the same channel. If the source reference RF signal is QCL Type B, the receiver can use the source reference RF signal to estimate the Doppler shift and Doppler spread of a second reference RF signal transmitted on the same channel. If the source reference RF signal is QCL Type C, the receiver can use the source reference RF signal to estimate the Doppler shift and average delay of a second reference RF signal transmitted on the same channel. If the source reference RF signal is QCL Type D, the receiver can use the source reference RF signal to estimate the spatial receive parameter of a second reference RF signal transmitted on the same channel.

In receive beamforming, the receiver uses a receive beam to amplify RF signals detected on a given channel. For example, the receiver can increase the gain setting and/or adjust the phase setting of an array of antennas in a particular direction to amplify (e.g., to increase the gain level of) the RF signals received from that direction. Thus, when a receiver is said to beamform in a certain direction, it means the beam gain in that direction is high relative to the beam gain along other directions, or the beam gain in that direction is the highest compared to the beam gain in that direction of all other receive beams available to the receiver. This results in a stronger received signal strength (e.g., reference signal received power (RSRP), reference signal received quality (RSRQ), signal-to-interference-plus-noise ratio (SINR), etc.) of the RF signals received from that direction.

Transmit and receive beams may be spatially related. A spatial relation means that parameters for a second beam (e.g., a transmit or receive beam) for a second reference signal can be derived from information about a first beam (e.g., a receive beam or a transmit beam) for a first reference signal. For example, a UE may use a particular receive beam to receive a reference downlink reference signal (e.g., synchronization signal block (SSB)) from a base station. The UE can then form a transmit beam for sending an uplink reference signal (e.g., sounding reference signal (SRS)) to that base station based on the parameters of the receive beam.

Note that a “downlink” beam may be either a transmit beam or a receive beam, depending on the entity forming it. For example, if a base station is forming the downlink beam to transmit a reference signal to a UE, the downlink beam is a transmit beam. If the UE is forming the downlink beam, however, it is a receive beam to receive the downlink reference signal. Similarly, an “uplink” beam may be either a transmit beam or a receive beam, depending on the entity forming it. For example, if a base station is forming the uplink beam, it is an uplink receive beam, and if a UE is forming the uplink beam, it is an uplink transmit beam.

The electromagnetic spectrum is often subdivided, based on frequency/wavelength, into various classes, bands, channels, etc. In 5G NR two initial operating bands have been identified as frequency range designations FR1 (410 MHz-7.125 GHz) and FR2 (24.25 GHz-52.6 GHz). It should be understood that although a portion of FR1 is greater than 6 GHz, FR1 is often referred to (interchangeably) as a “Sub-6 GHz” band in various documents and articles. A similar nomenclature issue sometimes occurs with regard to FR2, which is often referred to (interchangeably) as a “millimeter wave” band in documents and articles, despite being different from the extremely high frequency (EHF) band (30 GHz-300 GHz) which is identified by the INTERNATIONAL TELECOMMUNICATION UNION® as a “millimeter wave” band.

The frequencies between FR1 and FR2 are often referred to as mid-band frequencies. Recent 5G NR studies have identified an operating band for these mid-band frequencies as frequency range designation FR3 (7.125 GHz-24.25 GHz). Frequency bands falling within FR3 may inherit FR1 characteristics and/or FR2 characteristics, and thus may effectively extend features of FR1 and/or FR2 into mid-band frequencies. In addition, higher frequency bands are currently being explored to extend 5G NR operation beyond 52.6 GHz. For example, three higher operating bands have been identified as frequency range designations FR4a or FR4-1 (52.6 GHz-71 GHz), FR4 (52.6 GHz-114.25 GHz), and FR5 (114.25 GHz-300 GHz). Each of these higher frequency bands falls within the EHF band.

With the above aspects in mind, unless specifically stated otherwise, it should be understood that the term “sub-6 GHz” or the like if used herein may broadly represent frequencies that may be less than 6 GHz, may be within FR1, or may include mid-band frequencies. Further, unless specifically stated otherwise, it should be understood that the term “millimeter wave” or the like if used herein may broadly represent frequencies that may include mid-band frequencies, may be within FR2, FR4, FR4-a or FR4-1, and/or FR5, or may be within the EHF band.

In a multi-carrier system, such as 5G, one of the carrier frequencies is referred to as the “primary carrier” or “anchor carrier” or “primary serving cell” or “PCell,” and the remaining carrier frequencies are referred to as “secondary carriers” or “secondary serving cells” or “SCells.” In carrier aggregation, the anchor carrier is the carrier operating on the primary frequency (e.g., FR1) utilized by a UE 104/182 and the cell in which the UE 104/182 either performs the initial radio resource control (RRC) connection establishment procedure or initiates the RRC connection re-establishment procedure. The primary carrier carries all common and UE-specific control channels, and may be a carrier in a licensed frequency (however, this is not always the case). A secondary carrier is a carrier operating on a second frequency (e.g., FR2) that may be configured once the RRC connection is established between the UE 104 and the anchor carrier and that may be used to provide additional radio resources. In some cases, the secondary carrier may be a carrier in an unlicensed frequency. The secondary carrier may contain only necessary signaling information and signals, for example, those that are UE-specific may not be present in the secondary carrier, since both primary uplink and downlink carriers are typically UE-specific. This means that different UEs 104/182 in a cell may have different downlink primary carriers. The same is true for the uplink primary carriers. The network is able to change the primary carrier of any UE 104/182 at any time. This is done, for example, to balance the load on different carriers. Because a “serving cell” (whether a PCell or an SCell) corresponds to a carrier frequency/component carrier over which some base station is communicating, the term “cell,” “serving cell,” “component carrier,” “carrier frequency,” and the like can be used interchangeably.

For example, still referring to FIG. 1, one of the frequencies utilized by the macro cell base stations 102 may be an anchor carrier (or “PCell”) and other frequencies utilized by the macro cell base stations 102 and/or the mmW base station 180 may be secondary carriers (“SCells”). The simultaneous transmission and/or reception of multiple carriers enables the UE 104/182 to significantly increase its data transmission and/or reception rates. For example, two 20 MHz aggregated carriers in a multi-carrier system would theoretically lead to a two-fold increase in data rate (i.e., 40 MHz), compared to that attained by a single 20 MHz carrier.

The wireless communications system 100 may further include a UE 164 that may communicate with a macro cell base station 102 over a communication link 120 and/or the mmW base station 180 over a mmW communication link 184. For example, the macro cell base station 102 may support a PCell and one or more SCells for the UE 164 and the mmW base station 180 may support one or more SCells for the UE 164.

In some cases, the UE 164 and the UE 182 may be capable of sidelink communication. Sidelink-capable UEs (SL-UEs) may communicate with base stations 102 over communication links 120 using the Uu interface (i.e., the air interface between a UE and a base station). SL-UEs (e.g., UE 164, UE 182) may also communicate directly with each other over a wireless sidelink 160 using the PC5 interface (i.e., the air interface between sidelink-capable UEs). A wireless sidelink (or just “sidelink”) is an adaptation of the core cellular (e.g., LTE, NR) standard that allows direct communication between two or more UEs without the communication needing to go through a base station. Sidelink communication may be unicast or multicast, and may be used for device-to-device (D2D) media-sharing, vehicle-to-vehicle (V2V) communication, vehicle-to-everything (V2X) communication (e.g., cellular V2X (cV2X) communication, enhanced V2X (eV2X) communication, etc.), emergency rescue applications, etc. One or more of a group of SL-UEs utilizing sidelink communications may be within the geographic coverage area 110 of a base station 102. Other SL-UEs in such a group may be outside the geographic coverage area 110 of a base station 102 or be otherwise unable to receive transmissions from a base station 102. In some cases, groups of SL-UEs communicating via sidelink communications may utilize a one-to-many (1:M) system in which each SL-UE transmits to every other SL-UE in the group. In some cases, a base station 102 facilitates the scheduling of resources for sidelink communications. In other cases, sidelink communications are carried out between SL-UEs without the involvement of a base station 102.

In an aspect, the sidelink 160 may operate over a wireless communication medium of interest, which may be shared with other wireless communications between other vehicles and/or infrastructure access points, as well as other RATs. A “medium” may be composed of one or more time, frequency, and/or space communication resources (e.g., encompassing one or more channels across one or more carriers) associated with wireless communication between one or more transmitter/receiver pairs. In an aspect, the medium of interest may correspond to at least a portion of an unlicensed frequency band shared among various RATs. Although different licensed frequency bands have been reserved for certain communication systems (e.g., by a government entity such as the Federal Communications Commission (FCC) in the United States), these systems, in particular those employing small cell access points, have recently extended operation into unlicensed frequency bands such as the Unlicensed National Information Infrastructure (U-NII) band used by wireless local area network (WLAN) technologies, most notably IEEE 802.11x WLAN technologies generally referred to as “Wi-Fi.” Example systems of this type include different variants of CDMA systems, TDMA systems, FDMA systems, orthogonal FDMA (OFDMA) systems, single-carrier FDMA (SC-FDMA) systems, and so on.

Note that although FIG. 1 only illustrates two of the UEs as SL-UEs (i.e., UEs 164 and 182), any of the illustrated UEs may be SL-UEs. Further, although only UE 182 was described as being capable of beamforming, any of the illustrated UEs, including UE 164, may be capable of beamforming. Where SL-UEs are capable of beamforming, they may beamform towards each other (i.e., towards other SL-UEs), towards other UEs (e.g., UEs 104), towards base stations (e.g., base stations 102, 180, small cell 102′, access point 150), etc. Thus, in some cases, UEs 164 and 182 may utilize beamforming over sidelink 160.

In the example of FIG. 1, any of the illustrated UEs (shown in FIG. 1 as a single UE 104 for simplicity) may receive signals 124 from one or more Earth orbiting space vehicles (SVs) 112 (e.g., satellites). In an aspect, the SVs 112 may be part of a satellite positioning system that a UE 104 can use as an independent source of location information. A satellite positioning system typically includes a system of transmitters (e.g., SVs 112) positioned to enable receivers (e.g., UEs 104) to determine their location on or above the Earth based, at least in part, on positioning signals (e.g., signals 124) received from the transmitters. Such a transmitter typically transmits a signal marked with a repeating pseudo-random noise (PN) code of a set number of chips. While typically located in SVs 112, transmitters may sometimes be located on ground-based control stations, base stations 102, and/or other UEs 104. A UE 104 may include one or more dedicated receivers specifically designed to receive signals 124 for deriving geo location information from the SVs 112.

In a satellite positioning system, the use of signals 124 can be augmented by various satellite-based augmentation systems (SBAS) that may be associated with or otherwise enabled for use with one or more global and/or regional navigation satellite systems. For example an SBAS may include an augmentation system(s) that provides integrity information, differential corrections, etc., such as the Wide Area Augmentation System (WAAS), the European Geostationary Navigation Overlay Service (EGNOS), the Multi-functional Satellite Augmentation System (MSAS), the Global Positioning System (GPS) Aided Geo Augmented Navigation or GPS and Geo Augmented Navigation system (GAGAN), and/or the like. Thus, as used herein, a satellite positioning system may include any combination of one or more global and/or regional navigation satellites associated with such one or more satellite positioning systems.

In an aspect, SVs 112 may additionally or alternatively be part of one or more non-terrestrial networks (NTNs). In an NTN, an SV 112 is connected to an earth station (also referred to as a ground station, NTN gateway, or gateway), which in turn is connected to an element in a 5G network, such as a modified base station 102 (without a terrestrial antenna) or a network node in a 5GC. This element would in turn provide access to other elements in the 5G network and ultimately to entities external to the 5G network, such as Internet web servers and other user devices. In that way, a UE 104 may receive communication signals (e.g., signals 124) from an SV 112 instead of, or in addition to, communication signals from a terrestrial base station 102.

The wireless communications system 100 may further include one or more UEs, such as UE 190, that connects indirectly to one or more communication networks via one or more device-to-device (D2D) peer-to-peer (P2P) links (referred to as “sidelinks”). In the example of FIG. 1, UE 190 has a D2D P2P link 192 with one of the UEs 104 connected to one of the base stations 102 (e.g., through which UE 190 may indirectly obtain cellular connectivity) and a D2D P2P link 194 with WLAN STA 152 connected to the WLAN AP 150 (through which UE 190 may indirectly obtain WLAN-based Internet connectivity). In an example, the D2D P2P links 192 and 194 may be supported with any well-known D2D RAT, such as LTE Direct (LTE-D), WI-FI DIRECT®, BLUETOOTH®, and so on.

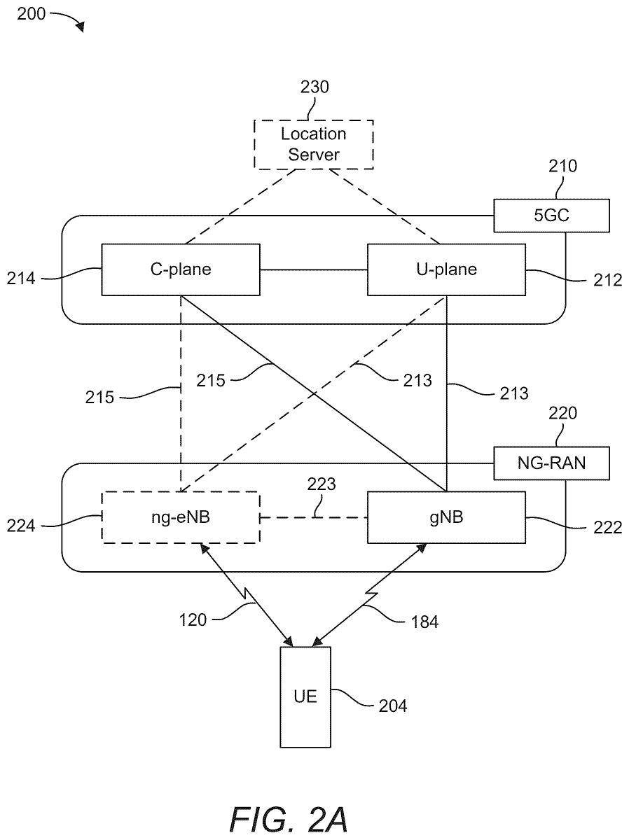

FIG. 2A illustrates an example wireless network structure 200. For example, a 5GC 210 (also referred to as a Next Generation Core (NGC)) can be viewed functionally as control plane (C-plane) functions 214 (e.g., UE registration, authentication, network access, gateway selection, etc.) and user plane (U-plane) functions 212, (e.g., UE gateway function, access to data networks, IP routing, etc.) which operate cooperatively to form the core network. User plane interface (NG-U) 213 and control plane interface (NG-C) 215 connect the gNB 222 to the 5GC 210 and specifically to the user plane functions 212 and control plane functions 214, respectively. In an additional configuration, an ng-eNB 224 may also be connected to the 5GC 210 via NG-C 215 to the control plane functions 214 and NG-U 213 to user plane functions 212. Further, ng-eNB 224 may directly communicate with gNB 222 via a backhaul connection 223. In some configurations, a Next Generation RAN (NG-RAN) 220 may have one or more gNBs 222, while other configurations include one or more of both ng-eNBs 224 and gNBs 222. Either (or both) gNB 222 or ng-eNB 224 may communicate with one or more UEs 204 (e.g., any of the UEs described herein).

Another optional aspect may include a location server 230, which may be in communication with the 5GC 210 to provide location assistance for UE(s) 204. The location server 230 can be implemented as a plurality of separate servers (e.g., physically separate servers, different software modules on a single server, different software modules spread across multiple physical servers, etc.), or alternately may each correspond to a single server. The location server 230 can be configured to support one or more location services for UEs 204 that can connect to the location server 230 via the core network, 5GC 210, and/or via the Internet (not illustrated). Further, the location server 230 may be integrated into a component of the core network, or alternatively may be external to the core network (e.g., a third party server, such as an original equipment manufacturer (OEM) server or service server).

FIG. 2B illustrates another example wireless network structure 240. A 5GC 260 (which may correspond to 5GC 210 in FIG. 2A) can be viewed functionally as control plane functions, provided by an access and mobility management function (AMF) 264, and user plane functions, provided by a user plane function (UPF) 262, which operate cooperatively to form the core network (i.e., 5GC 260). The functions of the AMF 264 include registration management, connection management, reachability management, mobility management, lawful interception, transport for session management (SM) messages between one or more UEs 204 (e.g., any of the UEs described herein) and a session management function (SMF) 266, transparent proxy services for routing SM messages, access authentication and access authorization, transport for short message service (SMS) messages between the UE 204 and the short message service function (SMSF) (not shown), and security anchor functionality (SEAF). The AMF 264 also interacts with an authentication server function (AUSF) (not shown) and the UE 204, and receives the intermediate key that was established as a result of the UE 204 authentication process. In the case of authentication based on a UMTS (universal mobile telecommunications system) subscriber identity module (USIM), the AMF 264 retrieves the security material from the AUSF. The functions of the AMF 264 also include security context management (SCM). The SCM receives a key from the SEAF that it uses to derive access-network specific keys. The functionality of the AMF 264 also includes location services management for regulatory services, transport for location services messages between the UE 204 and a location management function (LMF) 270 (which acts as a location server 230), transport for location services messages between the NG-RAN 220 and the LMF 270, evolved packet system (EPS) bearer identifier allocation for interworking with the EPS, and UE 204 mobility event notification. In addition, the AMF 264 also supports functionalities for non-3GPP® (Third Generation Partnership Project) access networks.

Functions of the UPF 262 include acting as an anchor point for intra/inter-RAT mobility (when applicable), acting as an external protocol data unit (PDU) session point of interconnect to a data network (not shown), providing packet routing and forwarding, packet inspection, user plane policy rule enforcement (e.g., gating, redirection, traffic steering), lawful interception (user plane collection), traffic usage reporting, quality of service (QoS) handling for the user plane (e.g., uplink/downlink rate enforcement, reflective QoS marking in the downlink), uplink traffic verification (service data flow (SDF) to QoS flow mapping), transport level packet marking in the uplink and downlink, downlink packet buffering and downlink data notification triggering, and sending and forwarding of one or more “end markers” to the source RAN node. The UPF 262 may also support transfer of location services messages over a user plane between the UE 204 and a location server, such as an SLP 272.

The functions of the SMF 266 include session management, UE Internet protocol (IP) address allocation and management, selection and control of user plane functions, configuration of traffic steering at the UPF 262 to route traffic to the proper destination, control of part of policy enforcement and QoS, and downlink data notification. The interface over which the SMF 266 communicates with the AMF 264 is referred to as the N11 interface.

Another optional aspect may include an LMF 270, which may be in communication with the 5GC 260 to provide location assistance for UEs 204. The LMF 270 can be implemented as a plurality of separate servers (e.g., physically separate servers, different software modules on a single server, different software modules spread across multiple physical servers, etc.), or alternately may each correspond to a single server. The LMF 270 can be configured to support one or more location services for UEs 204 that can connect to the LMF 270 via the core network, 5GC 260, and/or via the Internet (not illustrated). The SLP 272 may support similar functions to the LMF 270, but whereas the LMF 270 may communicate with the AMF 264, NG-RAN 220, and UEs 204 over a control plane (e.g., using interfaces and protocols intended to convey signaling messages and not voice or data), the SLP 272 may communicate with UEs 204 and external clients (e.g., third-party server 274) over a user plane (e.g., using protocols intended to carry voice and/or data like the transmission control protocol (TCP) and/or IP).

Yet another optional aspect may include a third-party server 274, which may be in communication with the LMF 270, the SLP 272, the 5GC 260 (e.g., via the AMF 264 and/or the UPF 262), the NG-RAN 220, and/or the UE 204 to obtain location information (e.g., a location estimate) for the UE 204. As such, in some cases, the third-party server 274 may be referred to as a location services (LCS) client or an external client. The third-party server 274 can be implemented as a plurality of separate servers (e.g., physically separate servers, different software modules on a single server, different software modules spread across multiple physical servers, etc.), or alternately may each correspond to a single server.

User plane interface 263 and control plane interface 265 connect the 5GC 260, and specifically the UPF 262 and AMF 264, respectively, to one or more gNBs 222 and/or ng-eNBs 224 in the NG-RAN 220. The interface between gNB(s) 222 and/or ng-eNB(s) 224 and the AMF 264 is referred to as the “N2” interface, and the interface between gNB(s) 222 and/or ng-eNB(s) 224 and the UPF 262 is referred to as the “N3” interface. The gNB(s) 222 and/or ng-eNB(s) 224 of the NG-RAN 220 may communicate directly with each other via backhaul connections 223, referred to as the “Xn-C” interface. One or more of gNBs 222 and/or ng-eNBs 224 may communicate with one or more UEs 204 over a wireless interface, referred to as the “Uu” interface.

The functionality of a gNB 222 may be divided between a gNB central unit (gNB-CU) 226, one or more gNB distributed units (gNB-DUs) 228, and one or more gNB radio units (gNB-RUs) 229. A gNB-CU 226 is a logical node that includes the base station functions of transferring user data, mobility control, radio access network sharing, positioning, session management, and the like, except for those functions allocated exclusively to the gNB-DU(s) 228. More specifically, the gNB-CU 226 generally host the radio resource control (RRC), service data adaptation protocol (SDAP), and packet data convergence protocol (PDCP) protocols of the gNB 222. A gNB-DU 228 is a logical node that generally hosts the radio link control (RLC) and medium access control (MAC) layer of the gNB 222. Its operation is controlled by the gNB-CU 226. One gNB-DU 228 can support one or more cells, and one cell is supported by only one gNB-DU 228. The interface 232 between the gNB-CU 226 and the one or more gNB-DUs 228 is referred to as the “F1” interface. The physical (PHY) layer functionality of a gNB 222 is generally hosted by one or more standalone gNB-RUs 229 that perform functions such as power amplification and signal transmission/reception. The interface between a gNB-DU 228 and a gNB-RU 229 is referred to as the “Fx” interface. Thus, a UE 204 communicates with the gNB-CU 226 via the RRC, SDAP, and PDCP layers, with a gNB-DU 228 via the RLC and MAC layers, and with a gNB-RU 229 via the PHY layer.

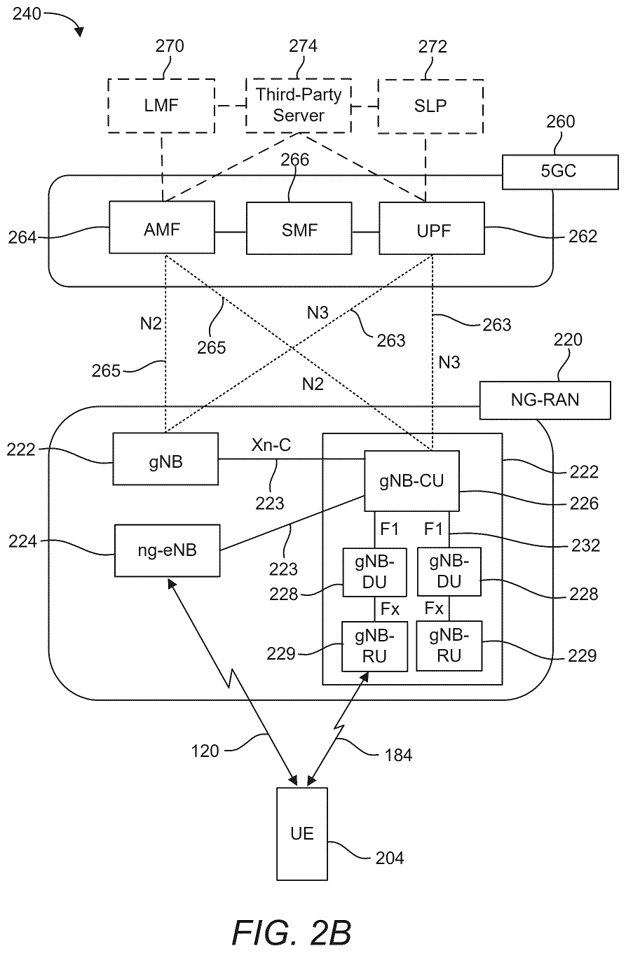

FIG. 3 illustrates several example components (represented by corresponding blocks) that may be incorporated into a UE 304 (which may correspond to any of the UEs described herein). It will be appreciated that these components may be implemented in different types of apparatuses in different implementations (e.g., in an application-specific integrated circuit (ASIC), in a system-on-chip (SoC), etc.). The illustrated components may also be incorporated into other apparatuses in a communication system. For example, other apparatuses in a system may include components similar to those described to provide similar functionality. Also, a given apparatus may contain one or more of the components. For example, an apparatus may include multiple transceiver components that enable the apparatus to operate on multiple carriers and/or communicate via different technologies.

The UE 304 includes one or more wireless wide area network (WWAN) transceivers 310 providing means for communicating (e.g., means for transmitting, means for receiving, means for measuring, means for tuning, means for refraining from transmitting, etc.) via one or more wireless communication networks (not shown), such as an NR network, an LTE network, a GSM network, and/or the like. The one or more WWAN transceivers 310 may each be connected to one or more antennas 316 for communicating with other network nodes, such as other UEs, access points, base stations (e.g., eNBs, gNBs), etc., via at least one designated RAT (e.g., NR, LTE, GSM, etc.) over a wireless communication medium of interest (e.g., some set of time/frequency resources in a particular frequency spectrum). The one or more WWAN transceivers 310 may be variously configured for transmitting and encoding signals 318 (e.g., messages, indications, information, and so on) and, conversely, for receiving and decoding signals 318 (e.g., messages, indications, information, pilots, and so on) in accordance with the designated RAT. Specifically, the one or more WWAN transceivers 310 include one or more transmitters 314 for transmitting and encoding signals 318 and one or more receivers 312 for receiving and decoding signals 318.

The UE 304 also includes, at least in some cases, one or more short-range wireless transceivers 320. The one or more short-range wireless transceivers 320 may be connected to one or more antennas 326 and provide means for communicating (e.g., means for transmitting, means for receiving, means for measuring, means for tuning, means for refraining from transmitting, etc.) with other network nodes, such as other UEs, access points, base stations, etc., via at least one designated RAT (e.g., Wi-Fi, LTE-D, BLUETOOTH®, ZIGBEE®, Z-WAVE®, PC5, dedicated short-range communications (DSRC), wireless access for vehicular environments (WAVE), near-field communication (NFC), ultra-wideband (UWB), etc.) over a wireless communication medium of interest. The one or more short-range wireless transceivers 320 may be variously configured for transmitting and encoding signals 328 (e.g., messages, indications, information, and so on) and, conversely, for receiving and decoding signals 328 (e.g., messages, indications, information, pilots, and so on) in accordance with the designated RAT. Specifically, the one or more short-range wireless transceivers 320 include one or more transmitters 324 for transmitting and encoding signals 328 and one or more receivers 322 for receiving and decoding signals 328. As specific examples, the one or more short-range wireless transceivers 320 may be Wi-Fi transceivers, BLUETOOTH® transceivers, ZIGBEE® and/or Z-WAVE® transceivers, NFC transceivers, UWB transceivers, or vehicle-to-vehicle (V2V) and/or vehicle-to-everything (V2X) transceivers.

The UE 304 also includes, at least in some cases, a satellite signal interface 330, which includes one or more satellite signal receivers 332 and may optionally include one or more satellite signal transmitters 334. The one or more satellite signal receivers 332 may be connected to one or more antennas 336 and may provide means for receiving and/or measuring satellite positioning/communication signals 338. Where the one or more satellite signal receivers 332 include a satellite positioning system receiver, the satellite positioning/communication signals 338 may be global positioning system (GPS) signals, global navigation satellite system (GLONASS) signals, Galileo signals, Beidou signals, Indian Regional Navigation Satellite System (NAVIC), Quasi-Zenith Satellite System (QZSS), etc. Where the one or more satellite signal receivers 332 include a non-terrestrial network (NTN) receiver, the satellite positioning/communication signals 338 may be communication signals (e.g., carrying control and/or user data) originating from a 5G network. The one or more satellite signal receivers 332 may comprise any suitable hardware and/or software for receiving and processing satellite positioning/communication signals 338. The one or more satellite signal receivers 332 may request information and operations as appropriate from the other systems, and, at least in some cases, perform calculations to determine locations of the UE 304 using measurements obtained by any suitable satellite positioning system algorithm.

The optional satellite signal transmitter(s) 334, when present, may be connected to the one or more antennas 336 and may provide means for transmitting satellite positioning/communication signals 338. Where the one or more satellite signal transmitters 334 include an NTN transmitter, the satellite positioning/communication signals 338 may be communication signals (e.g., carrying control and/or user data) originating from a 5G network. The one or more satellite signal transmitters 334 may comprise any suitable hardware and/or software for transmitting satellite positioning/communication signals 338. The one or more satellite signal transmitters 334 may request information and operations as appropriate from the other systems.

A transceiver may be configured to communicate over a wired or wireless link. A transceiver (whether a wired transceiver or a wireless transceiver) includes transmitter circuitry (e.g., transmitters 314, 324) and receiver circuitry (e.g., receivers 312, 322). A transceiver may be an integrated device (e.g., embodying transmitter circuitry and receiver circuitry in a single device) in some implementations, may comprise separate transmitter circuitry and separate receiver circuitry in some implementations, or may be embodied in other ways in other implementations. The transmitter circuitry and receiver circuitry of a wired transceiver may be coupled to one or more wired network interface ports. Wireless transmitter circuitry (e.g., transmitters 314, 324) may include or be coupled to a plurality of antennas (e.g., antennas 316, 326), such as an antenna array, that permits the respective apparatus (e.g., UE 304) to perform transmit “beamforming,” as described herein. Similarly, wireless receiver circuitry (e.g., receivers 312, 322) may include or be coupled to a plurality of antennas (e.g., antennas 316, 326), such as an antenna array, that permits the respective apparatus (e.g., UE 304) to perform receive beamforming, as described herein. In an aspect, the transmitter circuitry and receiver circuitry may share the same plurality of antennas (e.g., antennas 316, 326), such that the respective apparatus can only receive or transmit at a given time, not both at the same time. A wireless transceiver (e.g., the one or more WWAN transceivers 310, the one or more short-range wireless transceivers 320) may also include a network listen module (NLM) or the like for performing various measurements.

As used herein, the various wireless transceivers (e.g., transceivers 310, 320) and wired transceivers may generally be characterized as “a transceiver,” “at least one transceiver,” or “one or more transceivers.” As such, whether a particular transceiver is a wired or wireless transceiver may be inferred from the type of communication performed. For example, backhaul communication between network devices or servers will generally relate to signaling via a wired transceiver, whereas wireless communication between a UE (e.g., UE 304) and a base station will generally relate to signaling via a wireless transceiver.

The UE 304 also includes other components that may be used in conjunction with the operations as disclosed herein. The UE 304 includes one or more processors 342 for providing functionality relating to, for example, wireless communication, and for providing other processing functionality. The one or more processors 342 may therefore provide means for processing, such as means for determining, means for calculating, means for receiving, means for transmitting, means for indicating, etc. In an aspect, the one or more processors 342 may include, for example, one or more general purpose processors, multi-core processors, central processing units (CPUs), ASICs, digital signal processors (DSPs), field programmable gate arrays (FPGAs), other programmable logic devices or processing circuitry, or various combinations thereof.

The UE 304 includes memory circuitry implementing memory 340 (e.g., each including a memory device) for maintaining information (e.g., information indicative of reserved resources, thresholds, parameters, and so on). The memory 340 may therefore provide means for storing, means for retrieving, means for maintaining, etc. In some cases, the UE 304 may include a RFFE/DFE reception component 348. The RFFE/DFE reception component 348 may be hardware circuits that are part of or coupled to the one or more processors 342 that, when executed, cause the UE 304 to perform the functionality described herein. In other aspects, the RFFE/DFE reception component 348 may be external to the processors 342 (e.g., part of a modem processing system, integrated with another processing system, etc.). Alternatively, the RFFE/DFE reception component 348 may be a memory module stored in the memory 340 that, when executed by the one or more processors 342 (or a modem processing system, another processing system, etc.), cause the UE 304 to perform the functionality described herein. FIG. 3 illustrates possible locations of the RFFE/DFE reception component 348, which may be, for example, part of the one or more WWAN transceivers 310, the memory 340, the one or more processors 342, or any combination thereof, or may be a standalone component.

The UE 304 may include one or more sensors 344 coupled to the one or more processors 342 to provide means for sensing or detecting movement and/or orientation information that is independent of motion data derived from signals received by the one or more WWAN transceivers 310, the one or more short-range wireless transceivers 320, and/or the satellite signal interface 330. By way of example, the sensor(s) 344 may include one or more accelerometers (e.g., micro-electrical mechanical systems (MEMS) devices), a gyroscope, a geomagnetic sensor (e.g., a compass), an altimeter (e.g., a barometric pressure altimeter), and/or any other type of movement detection sensor. Moreover, the sensor(s) 344 may include a plurality of different types of devices and combine their outputs in order to provide motion information. For example, the sensor(s) 344 may use a combination of a multi-axis accelerometer and orientation sensors to provide the ability to compute positions in two-dimensional (2D) and/or three-dimensional (3D) coordinate systems. Note that at least the accelerometer and gyroscope may be referred to as “inertial” sensors.

The various components of the UE 304 may be communicatively coupled to each other over a data bus 308. In an aspect, the data bus 308 may form, or be part of, a communication interface of the UE 304.

In addition, the UE 304 includes a user interface 346 providing means for providing indications (e.g., audible and/or visual indications) to a user and/or for receiving user input (e.g., upon user actuation of a sensing device such a keypad, a touch screen, a microphone, and so on).

For convenience, the UE 304 is shown in FIG. 3 as including various components that may be configured according to the various examples described herein. It will be appreciated, however, that the illustrated components may have different functionality in different designs. In particular, various components in FIG. 3 are optional in alternative configurations and the various aspects include configurations that may vary due to design choice, costs, use of the device, or other considerations. For example, a particular implementation of UE 304 may omit the WWAN transceiver(s) 310 (e.g., a wearable device or tablet computer or PC or laptop may have Wi-Fi and/or BLUEOOTH® capability without cellular capability), or may omit the short-range wireless transceiver(s) 320 (e.g., cellular-only, etc.), or may omit the satellite signal interface 330, or may omit the sensor(s) 344, and so on. For brevity, illustration of the various alternative configurations is not provided herein, but would be readily understandable to one skilled in the art.

The components of FIG. 3 may be implemented in various ways. In some implementations, the components of FIG. 3 may be implemented in one or more circuits such as, for example, one or more processors and/or one or more ASICs (which may include one or more processors). Here, each circuit may use and/or incorporate at least one memory component for storing information or executable code used by the circuit to provide this functionality. For example, some or all of the functionality represented by blocks 310 to 346 may be implemented by processor and memory component(s) of the UE 304 (e.g., by execution of appropriate code and/or by appropriate configuration of processor components). For simplicity, various operations, acts, and/or functions are described herein as being performed “by a UE.” However, as will be appreciated, such operations, acts, and/or functions may actually be performed by specific components or combinations of components of the UE 304, such as the one or more processors 342, the one or more transceivers 310 and 320, the memory 340, the RFFE/DFE reception component 348, etc.

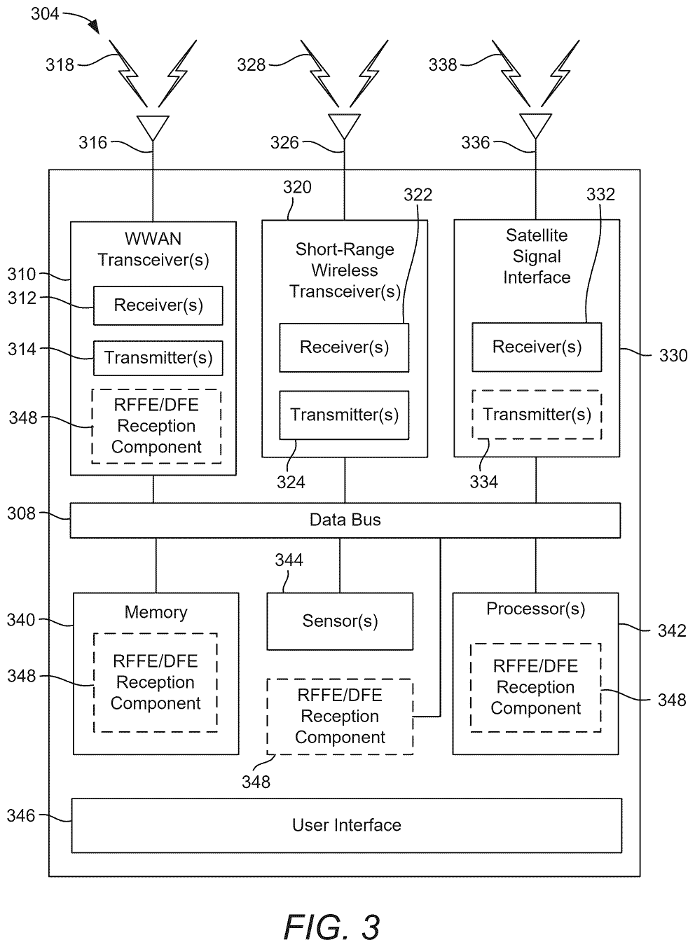

In LTE and, at least in some cases, NR, positioning measurements are reported through higher layer signaling, specifically, LTE positioning protocol (LPP) and/or RRC. LPP is used point-to-point between a location server (e.g., location server 230, LMF 270, SLP 272) and a UE (e.g., any of the UEs described herein) in order to position the UE using location related measurements obtained from one or more reference sources. FIG. 4 is a diagram 400 illustrating example LPP reference sources for positioning. In the example of FIG. 4, a target device, specifically a UE 404 (e.g., any of the UEs described herein), is engaged in an LPP session with a location server 430 (labeled as an “E-SMLC/SLP” in the specific example of FIG. 4). The UE 404 is also receiving/measuring wireless positioning signals from a first reference source, specifically one or more base stations 402 (which may correspond to any of the base stations described herein, and which is labelled as an “eNode B” in the specific example of FIG. 4), and a second reference source, specifically one or more solar power satellite (SPS) satellites 408 (which may correspond to SVs 112 in FIG. 1).

An LPP session is used between a location server 430 and a UE 404 in order to obtain location-related measurements or a location estimate or to transfer assistance data. A single LPP session is used to support a single location request (e.g., for a single mobile-terminated location request (MT-LR), mobile originated location request (MO-LR), or network induced location request (NI-LR)). Multiple LPP sessions can be used between the same endpoints to support multiple different location requests. Each LPP session comprises one or more LPP transactions, with each LPP transaction performing a single operation (e.g., capability exchange, assistance data transfer, location information transfer). LPP transactions are referred to as LPP procedures. The instigator of an LPP session instigates the first LPP transaction, but subsequent transactions may be instigated by either endpoint. LPP transactions within a session may occur serially or in parallel. LPP transactions are indicated at the LPP protocol level with a transaction identifier in order to associate messages with one another (e.g., request and response). Messages within a transaction are linked by a common transaction identifier.

LPP signaling can be used to request and report measurements related to the following positioning methods: observed time difference of arrival (OTDOA), downlink time difference of arrival (DL-TDOA), assisted global navigation satellite system (A-GNSS), LTE enhanced cell identity (E-CID), NR E-CID, sensor, terrestrial beacon system (TBS), WLAN, Bluetooth, downlink angle of departure (DL-AoD), uplink angle of arrival (UL-AoA), and multi-round-trip-time (RTT). Currently, LPP measurement reports may contain the following measurements: (1) one or more time of arrival (ToA), time difference of arrival (TDOA), reference signal time difference (RSTD), or reception-to-transmission (Rx-Tx) measurements, (2) one or more AoA and/or AoD measurements (currently only for a base station to report UL-AoA and DL-AoD to the location server 430), (3) one or more multipath measurements (per-path ToA, reference signal received power (RSRP), AoA/AoD), (4) one or more motion states (e.g., walking, driving, etc.) and trajectories (currently only for the UE 404), and (5) one or more report quality indications. In the present disclosure, positioning measurements, such as the example measurements just listed, and regardless of the positioning technology, may be referred to collectively as positioning state information (PSI).

The UE 404 and/or the location server 430 may derive location information from one or more reference sources, illustrated in the example of FIG. 4 as SPS satellite(s) 408 and the base station(s) 402. Each reference source can be used to calculate an independent estimate of the location of the UE 404 using associated positioning techniques. In the example of FIG. 4, the UE 404 is measuring characteristics (e.g., ToA, RSRP, RSTD, etc.) of positioning signals received from the base station(s) 402 to calculate, or to assist the location server 430 to calculate, an estimate of the location of the UE 404 using one or more cellular network-based positioning methods (e.g., multi-RTT, OTDOA, DL-TDOA, DL-AoD, E-CID, etc.). Similarly, the UE 404 is measuring characteristics (e.g., ToA) of GNSS signals received from the SPS satellites 408 to triangulate its location in two or three dimensions, depending on the number of SPS satellites 408 measured. In some cases, the UE 404 or the location server 430 may combine the location solutions derived from each of the different positioning techniques to improve the accuracy of the final location estimate.

As noted above, the UE 404 uses LPP to report location related measurements obtained from different of reference sources (e.g., base stations 402, Bluetooth beacons, SPS satellites 408, WLAN access points, motion sensors, etc.). As an example, for GNSS-based positioning, the UE 404 uses the LPP information element (IE) “A-GNSS-ProvideLocationInformation” to provide location measurements (e.g., pseudo ranges, location estimate, velocity, etc.) to the location server 430, together with time information. It may also be used to provide a GNSS positioning-specific error reason. The “A-GNSS-ProvideLocationInformation” IE includes IEs such as “GNSS-SignalMeasurementInformation,” “GNSS-LocationInformation,” “GNSS-MeasurementList,” and “GNSS-Error.” The UE 404 includes the “GNSS-LocationInformation” IE when it provides location and optionally velocity information derived using GNSS or hybrid GNSS and other measurements to the location server 430. The UE 404 uses the “GNSS-SignalMeasurementInformation” IE to provide GNSS signal measurement information to the location server 430 and the GNSS network time association if requested by the location server 430. This information includes the measurements of code phase, Doppler, C/No, and optionally accumulated carrier phase, also referred to as accumulated delta range (ADR), which enable the UE assisted GNSS method where location is computed in the location server 430. The UE 404 uses the “GNSS-MeasurementList” IE to provide measurements of code phase, Doppler, C/No, and optionally accumulated carrier phase (or ADR).

As another example, for motion sensor-based positioning, the currently supported positioning methods use a barometric pressure sensor and a motion sensor. The UE 404 uses the LPP IE “Sensor-ProvideLocationInformation” to provide location information for sensor-based methods to the location server 430. It may also be used to provide a sensor-specific error reason. The UE 404 uses the “Sensor-MeasurementInformation” IE to provide sensor measurements (e.g., barometric readings) to the location server 430. The UE 404 uses the “Sensor-MotionInformation” to provide movement information to the location server 430. The movement information may comprise an ordered series of points. This information may be obtained by the UE 404 using one or more motion sensors (e.g., accelerometers, barometers, magnetometers, etc.).

As yet another example, for Bluetooth-based positioning, the UE 404 uses the “BT-ProvideLocationInformation” IE to provide measurements of one or more Bluetooth beacons to the location server 430. This IE may also be used to provide Bluetooth positioning specific error reason.

The designs and techniques described herein relate to NTN communication and positioning frequency band reception and time-shared processing. In some examples, a UE may use common modem hardware resources for NTN communication to also perform GNSS operations associated with acquisition and tracking. While the design and techniques described herein may enable efficient GNSS-based positioning services low-cost UEs, such as IoT devices, there may be a trade-off in that time sharing of the common modem hardware resources can have the impact on modem performance in certain areas, such as paging performance in an idle mode, or throughput loss in the connected and inactive mode.

It is to be appreciated that multiple opportunities, such as idle mode gaps, connected mode gaps, idle periods in the voice transmissions, bursty nature of data transmissions, etc. may be used to minimize potential paging or throughput loss by the UE when using the common modem hardware resources and time-sharing techniques described herein. Additionally, in accordance with some aspects, certain multi-subscriber identity module (SIM) device features and/or techniques may be applied to the common modem hardware resources used by the UE to support NTN communication and GNSS positioning processes.

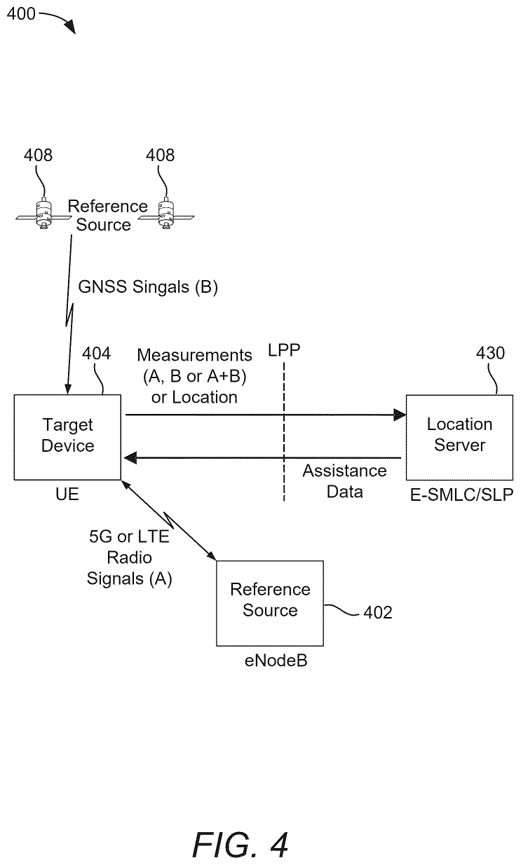

FIG. 5 illustrates an example NTN system 500 with satellite sources for communication and positioning, according to aspects of the disclosure. In some aspects, the NTN system 500 may include aspects of the wireless communication system 100 or other systems or networks described herein. In some aspects, an aerial base station/satellite 502 may include aspects of the base stations 102, 202, SV 112, or other base stations, satellites, or network devices described herein. In some aspects, a UE 504 may include aspects of the UEs 104, 204, 304, 404 or other UEs or network devices described herein. In some aspects, a GNSS satellite 508 may include aspects of SPS satellite 408, SV 112, or other base stations, satellites, or network devices described herein.

In some examples, the UE 504 may receive a first signal 512 from a communication source, such as the aerial base station/satellite 502. The UE 504 may receive a second signal 514 from a positioning satellite source, such as the GNSS satellite 508. In some cases, the UE 504 may use a common RFFE circuit block to concurrently receive both the first signal 512 from the aerial base station/satellite 502 and second signal 514 from the GNSS satellite 508. The UE 504 may store ADC samples corresponding to the first signal 512 received from the aerial base station/satellite 502. Additionally, the UE 504 may store ADC samples corresponding to the second signal 514 received from the GNSS satellite 508.

As illustrated in the example of FIG. 5, the communication source and the positioning satellite source originate from separate satellites. In some cases, however, a single satellite source may provide a communication signal and a positioning signal. The aerial base station/satellite 502 in the NTN system 500 may be communicatively coupled with one or more other aerial base station/satellites (not shown) and may be communicatively coupled with a ground station (not shown) that functions as an NTN gateway. That is, for example, the NTN system 500 may operate using a gateway on the ground to enable ground base stations to communicate with the aerial base station/satellite 502.

In some cases, the NTN system 500 can provide cellular coverage to rural areas or areas with rugged terrain where installing numerous base stations may be impracticable. In some implementations, the aerial base station/satellite 502 may be a low-Earth-orbit (LEO) satellite station (e.g., orbiting at an elevation between 300 and 1,500 km) or a high-altitude platform station (HAPS), which may hover at lower altitudes in the Earth's stratosphere.

In some aspects, the UE 504 may be an IoT device and share, update, and/or synchronize the information regarding communication and positioning between other UE or communication devices (not shown) in the NTN system 500. In some cases, the first signal 512 received from the aerial base station/satellite 502 may correspond to a 5G NTN FDD n255 DL frequency band. In some cases, the second signal 514 received from the GNSS satellite 508 may correspond to a GNSS L1 frequency band.

That is, for example, the 5G NTN FDD n255 DL frequency band ranges from 1,525 MHz to 1,559 MHz which may be close to the GNSS L1 frequency band. The GNSS L1 frequency band may have a center frequency of 1,575.42 MHz. As such, the RFFE circuit block of UE 504 may include a single RFFE circuit and wideband ADC circuit. In some cases, the sampling clock of the wideband ADC circuit may be fₛ=115.2 MHz.

In some aspects, time-sharing techniques of the UE 504 may include offline or real-time opportunistic processing of second signal 514 (e.g., corresponding to a GNSS signal) and the ADC samples thereof. That is, for example, the offline or real-time opportunistic processing may include using one or more measurement gaps associated with a WWAN transmission, a connected mode discontinuous reception (DRX) off period, an idle mode DRX off period, etc.

In some examples, the stored ADC samples associated with the first signal 512 and second signal 514 may be processed through a parallel DFE circuit block or shared DFE circuit block and stored in one or more memories by the UE 504. That is, for example, the ADC samples associated with the first signal 512 and second signal 514 may be stored after being received and processed by the RFFE circuit block. Then, the stored ADC samples associated with the first signal 512 may be further processed by a DFE circuit designed for communication signal processing (e.g., 5G NR signal processing), and the stored ADC samples associated with the second signal 514 may be further processed by a DFE circuit designed for positioning signal processing (e.g., GNSS signal processing).

In some examples, the output of the DFE circuit designed for positioning signal processing may also be stored for further post-processing through hardware blocks, software, or a combination thereof. Like the processing operation performed with respect to the DFE circuit block, the post-processing operation may be performed during one or more measurement gaps associated with a WWAN transmission, a connected mode DRX off period, an idle mode DRX off period, etc. Upon completion of the post-processing operation, the UE 504 may determine a single shot position fix. In some cases, the single shot position fix may be based on 1 second of integration, and as such the UE 504 may be implemented with one or more memories of 1 MB for storing 2-bit complex in-phase (I) and quadrature (Q) component (IQ) samples at 2.046 MHz.

In some examples, the ADC samples associated with the first signal 512 and second signal 514 received and processed by the RFFE circuit block may be temporarily stored and subsequently processed via switching to a common or shared DFE circuit block. That is, for example, the UE 504 may configure components (e.g., an intermediate frequency (IF) down conversion circuit) of the shared DFE circuit block with a first software configuration for use during a first time period. This first software configuration may be designed with parameters to configure the components of the shared DFE circuit block for communication signal processing (e.g., 5G NR signal processing).

The UE 504 may also configure the components of the shared DFE circuit block with a second software configuration for use during a second time period. This second software configuration may be designed with parameters to configure the components of the shared DFE circuit block for positioning signal processing (e.g., GNSS signal processing). It is to be noted that at least some parameters associated with the second software configuration may be different from the corresponding parameters associated with the first software configuration.

Non-limiting examples of RFFE circuit blocks, DFE circuit blocks, post-processing circuit blocks, as well as other circuits, processes, and time-sharing techniques that may be implemented in the UE 504 are described herein.

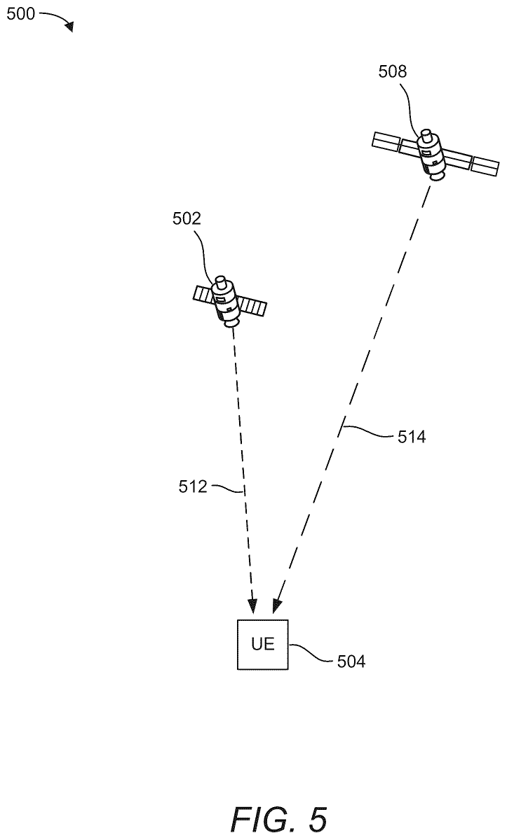

FIG. 6 illustrates an example frequency range diagram 600 for reception of communication and positioning signals, according to aspects of the disclosure. The frequency range diagram 600 illustrates an example of a communication frequency band and a positioning frequency band, for which a local oscillator (LO) of an RFFE circuit and a sampling clock of a wideband ADC may be configured to receive and sample transmissions in both frequency bands.

For example, an RFFE circuit may have an LO configured to a radio frequency 616 between the 5G NTN FDD n255 DL frequency band 612 and the GNSS L1 frequency band 618. The radio frequency 616 of the LO may be set to 1,567 MHz in accordance with some examples. However, the radio frequency of the LO may be set to other values, for example, any value between an end of the 5G NTN FDD n255 DL frequency band 612 and a beginning the GNSS L1 frequency band 618. For example, the radio frequency 616 of the LO may be set to 1,567 MHz plus or minus 8 MHz, in accordance with some implementations.

As shown in the example of FIG. 6, the 5G NTN FDD n255 DL frequency band 612 ranges from 1,525 MHz to 1,559 MHz which may be proximate to the GNSS L1 frequency band having a center frequency of 1,575.42 MHz. Accordingly, when the radio frequency 616 of the LO of the RFFE circuit is set to 1,567 MHz and the sampling reference clock frequency for the wideband ADC circuit is set to 115.2 MHz (or greater in some implementations), the entire frequency range for the 5G NTN FDD n255 DL frequency band 612 and the GNSS L1 frequency band 618 may be received and sampled by the RFFE circuit block.

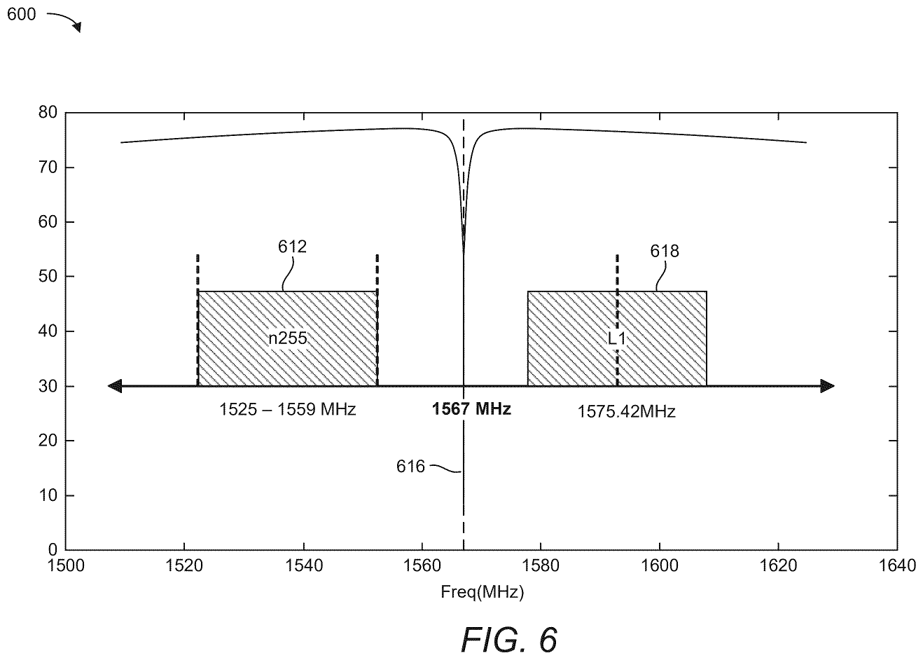

FIG. 7 illustrates an example timing diagram 700 for time-shared processing of communication and positioning signals, according to aspects of the disclosure. The timing diagram 700 may correspond to a WWAN DRX pattern in which UE active slots 712 and GNSS measurement slots 718 are scheduled. For example, processing operations associated with communication may be performed during the UE active slots 712.

Additionally, or alternatively, processing operations and/or post processing operations associated with positioning may be performed during the GNSS measurement slots 718. It is to be noted that other time-sharing techniques for processing communication and positioning signals are contemplated as described herein.

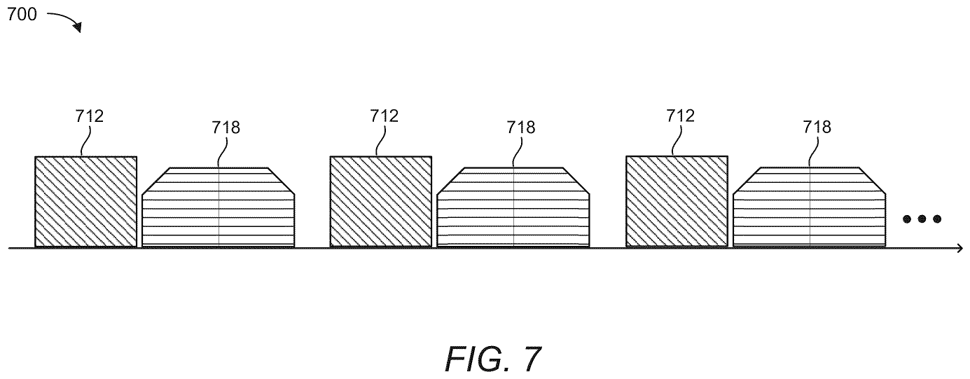

FIG. 8 illustrates a first block diagram 800 of example common modem hardware resources that may support NTN communication and positioning frequency band reception and time-shared processing, according to aspects of the disclosure. The first block diagram 800 corresponds to a common RFFE and parallel DFE design that may be implemented in a UE or network device, such as the UE 104, 204, 304, 404, 504 or other UEs or network devices described herein.

The components of FIG. 8 may be implemented in various ways. In some implementations, the components of FIG. 8 may be implemented in one or more circuits such as, for example, one or more processors and/or one or more application-specific integrated circuits (ASICs) (which may include one or more processors and one or more memories). The first block diagram 800 may include a common RFFE circuit block 810, a GNSS DFE circuit block 820, and a 5G DFE circuit block 830.

In some examples, the common RFFE circuit block 810 may include an RFFE circuit 812 that has the LO configured for 1,567 MHz and a wideband ADC circuit 814 that has a sampling reference clock frequency configured for 115.2 MHz. The common RFFE circuit block 810 may receive and sample NTN communication signals in the 5G NTN FDD n255 DL frequency band and GNSS positioning signals in the GNSS L1 frequency band.

In some cases, the wideband ADC circuit 814 may be operable to store ADC samples corresponding to the NTN communication signals and the GNSS positioning signals. The wideband ADC circuit 814 may also selectively forward the ADC samples corresponding to the NTN communication signals or the ADC samples corresponding to the GNSS positioning signals. For example, the wideband ADC circuit 814 may forward the stored ADC samples corresponding to the NTN communication signals to the 5G DFE circuit block 830 for processing. The 5G DFE circuit block 830 may be configured to process ADC samples corresponding to the NTN communication signals, as well as other ADC samples corresponding to 5G communication (e.g., signals received for a ground base station), in accordance with some aspects.

The wideband ADC circuit 814 may also forward the stored ADC samples corresponding to the GNSS positioning signals to the GNSS DFE circuit block 820 for processing. In some cases, the stored ADC samples corresponding to the GNSS positioning signals may be forwarded during a different time period than the stored ADC samples corresponding to the NTN communication signals. However, in some cases, the wideband ADC circuit 814 may forward the ADC samples corresponding to the GNSS positioning signals and the ADC samples corresponding to the NTN communication signals in real-time (e.g., simultaneously or approximately simultaneous) as the first block diagram 800 includes a parallel DFE design.

The GNSS DFE circuit block 820 may include any suitable hardware and/or software for receiving and processing GNSS signals including, but not limited to, an IF down converter circuit 816, resample at 80 times 1.023 MHz circuit 818, decimation anti-aliasing filter (AAF) circuit 822, decimate by 40 circuit 824, and a decimation equalizer circuit 826. The output of the GNSS DFE circuit block 820 may be 2-bit complex IQ samples at 2.046 MHz.

In some cases, the 2-bit complex IQ samples at 2.046 MHz may be stored in the one or more memories and scheduled for post-processing at a time to avoid missed opportunities for downlink communication reception. When GNSS post-processing operations occur either in real-time or offline, the input for GNSS post-processing may be information corresponding to the 2-bit complex IQ samples at 2.046 MHz. In some examples, a first mixer 828 may mix in a carrier Doppler compensation signal, second mixer 832 may mix in a locally generated reference pseudo-random noise sequence. In some examples, the GNSS post-processing may include a coherent integration process performed with coherent integration circuit 834 and/or non-coherent integration process performed with non-coherent integration circuit 836. That is, for example, depending on the signal-to-noise (SNR) achieved after the coherent integration process, the GNSS post-processing may further include the non-coherent integration process.

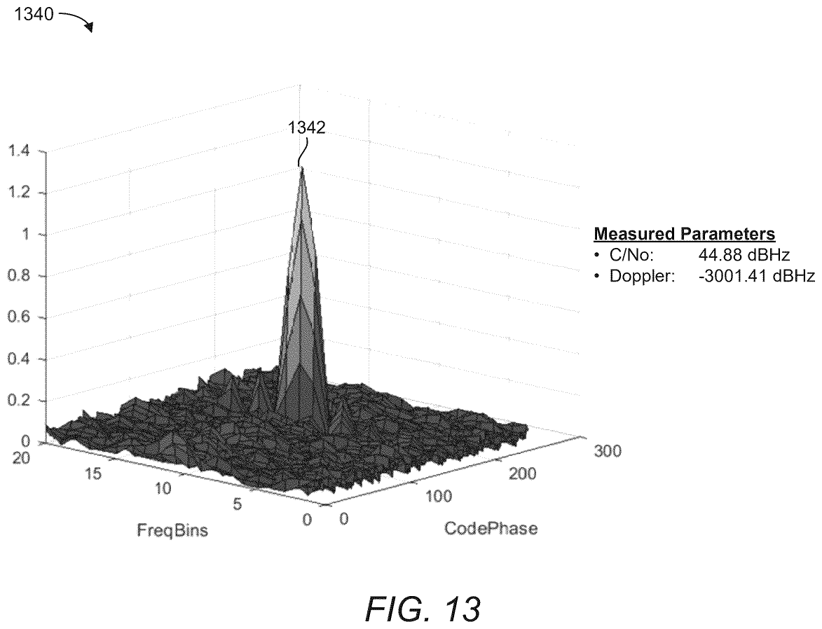

In some examples, the output of the GNSS post-processing may be an energy grid 840. An example energy grid corresponding to the energy grid 840 is illustrated in FIG. 13. The calculations for generating the energy grid 840 and determining a UE's position may be performed using measurements obtained by any suitable GNSS algorithm, in accordance with some aspects. In some examples, the single shot position fix may be based on the signal peak of the energy grid 840.

It is to be appreciated that other circuits and/or modifications of the circuits shown in the example of FIG. 8 may be made as would be apparent given the benefit of the disclosure.

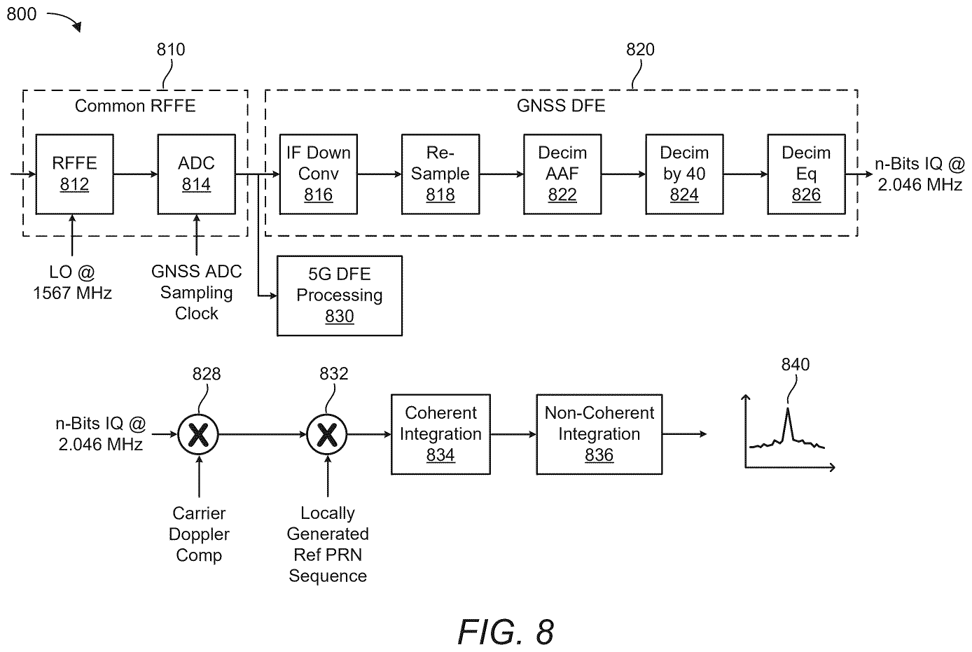

FIG. 9 illustrates a second block diagram 900 of example common modem hardware resources that may support NTN communication and positioning frequency band reception and time-shared processing, according to aspects of the disclosure. The first block diagram 900 corresponds to a common RFFE and DFE design that may be implemented in a UE or network device, such as the UE 104, 204, 304, 404, 504 or other UEs or network devices described herein.

The components of FIG. 9 may be implemented in various ways. In some implementations, the components of FIG. 9 may be implemented in one or more circuits such as, for example, one or more processors and/or one or more application-specific integrated circuits (ASICs) (which may include one or more processors and one or more memories). The second block diagram 900 may include a common RFFE and DFE circuit block 910.

In some examples, the common RFFE and DFE circuit block 910 may include an RFFE circuit 912 that has the LO configured for 1,567 MHz and a wideband ADC circuit 914 that has a sampling reference clock frequency configured for 115.2 MHz. The common RFFE and DFE circuit block 910 may receive and sample NTN communication signals in the 5G NTN FDD n255 DL frequency band and GNSS positioning signals in the GNSS L1 frequency band.

In some cases, the wideband ADC circuit 914 may be operable to store ADC samples corresponding to the NTN communication signals and the GNSS positioning signals. In some cases, the sampling reference clock of the wideband ADC circuit 914 operates continuously during a time period when the GNSS positioning signals in the GNSS L1 frequency band are received until post-processing of the stored ADC samples corresponding to the GNSS positioning signals is completed. The wideband ADC circuit 914 may also selectively switch the stored ADC samples corresponding to the NTN communication signals or the ADC samples corresponding to the GNSS positioning signals. That is, for example, a UE implemented with the second block diagram 900 may configure one or more components of the DFE circuit block portion of the common RFFE and DFE circuit block 910 with a first software configuration for the ADC samples corresponding to the NTN communication signals.

In some examples, the first software configuration may be configured to be active during a first time period for processing NTN communication signals. The one or more components of the DFE circuit block portion that are configured with the first software configuration may include an IF down converter circuit 916, resample at 80 times 1.023 MHz circuit 918, decimation anti-aliasing filter (AAF) circuit 922, decimate by 40 circuit 924, and a decimation equalizer circuit 926.

In some cases, the UE implemented with the second block diagram 900 may configure the one or more components of the DFE circuit block portion with a second software configuration for the ADC samples corresponding to the GNSS positioning signals. The second software configurations may be configured to be active during a second time period for opportunistically processing the GNSS positioning signals. In some cases, some of the software-configured parameters of the first and second software configurations may be the same. However, at least some of the software-configured parameters of the first and second software configuration are different, in accordance with some aspects.

The common RFFE and DFE circuit block 910 may include any suitable hardware and/or software for receiving and processing NTN communication and GNSS positioning signals including, but not limited to, the IF down converter circuit 916, resample at 80 times 1.023 MHz circuit 918, decimation anti-aliasing filter (AAF) circuit 922, decimate by 40 circuit 924, and a decimation equalizer circuit 926. The output of the common RFFE and DFE circuit block 910 may be 2-bit complex IQ samples at 2.046 MHz.

In some cases, the 2-bit complex IQ samples at 2.046 MHz for the GNSS positioning signals may be stored in the one or more memories and scheduled for post-processing at a time to avoid missed opportunities for downlink communication reception. When GNSS post-processing operations occur, the input for GNSS post-processing may be information corresponding to the 2-bit complex IQ samples at 2.046 MHz. In some examples, a first mixer 928 may mix in a carrier Doppler compensation signal, second mixer 932 may mix in a locally generated reference pseudo-random noise sequence.

In some examples, the GNSS post-processing may include a coherent integration process performed with coherent integration circuit 934 and/or non-coherent integration process performed with non-coherent integration circuit 936. That is, for example, depending on the SNR achieved after the coherent integration process, the GNSS post-processing may further include the non-coherent integration process.

In some examples, the output of the GNSS post-processing may be an energy grid 940. An example energy grid corresponding to the energy grid 940 is illustrated in FIG. 13. The calculations for generating the energy grid 940 and determining a UE's position may be performed using measurements obtained by any suitable GNSS algorithm, in accordance with some aspects. In some examples, the single shot position fix may be based on the signal peak of the energy grid 940.

It is to be appreciated that other circuits and/or modifications of the circuits shown in the example of FIG. 9 may be made as would be apparent given the benefit of the disclosure.

Additionally, it is to be noted that in some implementation scenarios, transmissions in the 5G NTN FDD n255 UL frequency band (e.g., 1626.5 to 1660.5 MHz) may cause jamming with respect to reception of the GNSS L1 frequency band. In such cases, when the common RFFE and DFE circuit block 910 having a shared DFE circuit for 5G NTN communication signal processing and GNSS positioning signal processing, the reception of the GNSS L1 frequency band positioning signal may be scheduled during a 5G NTN idle period. For example, a UE configured with the second block diagram 900 may receive an indication (e.g., one or more DCIs or other signaling) that a reception of the GNSS L1 frequency band positioning signal is scheduled for a first time period and a transmission in the 5G NTN FDD n255 UL frequency band is scheduled for a second time period that is different from the first time period.

In some examples, the separate transmission associated with the 5G NTN FDD n255 UL frequency band and reception of the GNSS L1 frequency band in such a signal jamming scenario may assist in avoiding unnecessary outage or signal loss with respect to the GNSS L1 frequency band positioning signal. That is, for example, the 5G NTN FDD n255 UL band transmission can pose a jamming threat to the GNSS L1 frequency band positioning signal reception in some scenarios. As such, the 5G NTN FDD n255 UL frequency band transmission and GNSS L1 frequency band positioning signal reception may be separated, in accordance with some aspects. It is to be noted that reception of the 5G NTN FDD n255 DL frequency band and the GNSS L1 frequency band positioning signal may still be concurrent in such scenarios.

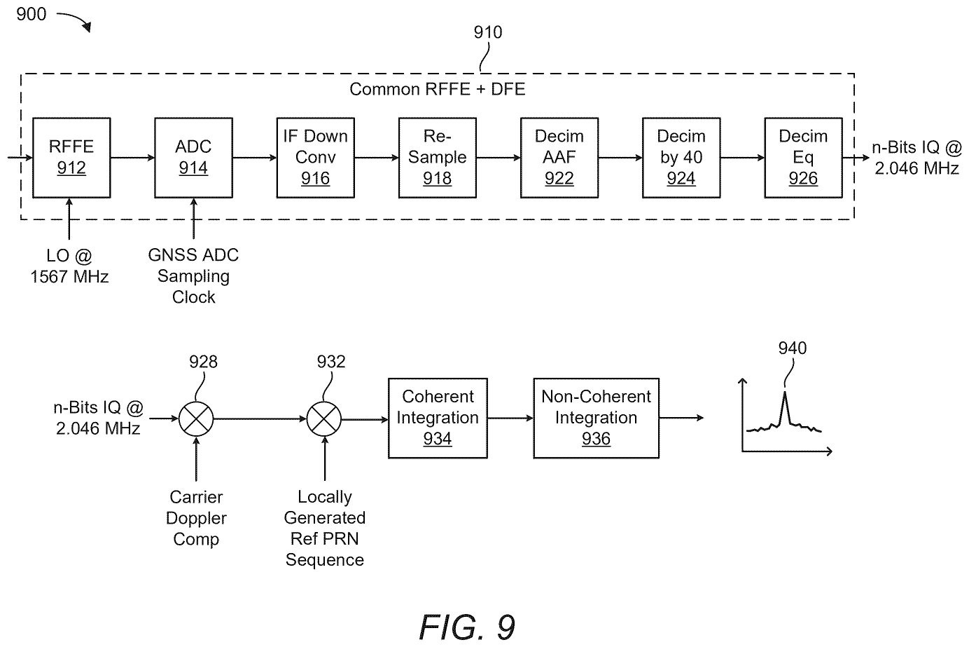

FIG. 10 illustrates a first timing diagram 1000 of an example positioning signal processing, according to aspects of the disclosure. The first timing diagram 1000 shows techniques for discarding stored ADC samples corresponding to GNSS positioning signals that may be used to support time-sharing of a UE's hardware resources. The first timing diagram 1000 may be implemented in a UE or network device, such as the UE 104, 204, 304, 404, 504 or other UEs or network devices described herein.

In some examples, the stored ADC samples corresponding to GNSS positioning signals arrive in the one or more memories of the UE at time instance 1012 and a discard timer starts at time instance 1014. While the UE is waiting for an opportunity to process stored ADC samples corresponding to GNSS positioning signals, the discard timer may expire at timing instance 1016. As such, the UE may discard the existing ADC samples corresponding to GNSS positioning signals stored in the one or more memories.

Additionally, or alternatively, the UE may receive an updated navigation message while waiting for an opportunity to process stored ADC samples corresponding to GNSS positioning signals. Similarly, the UE may discard the existing ADC samples corresponding to GNSS positioning signals that were stored in the one or more memories.

At time instance 1016, the UE may also start the process of storing new ADC samples corresponding to GNSS positioning signals. At time instance 1022, the collection of new ADC samples corresponding to GNSS positioning signals may be completed and stored in the one or more memories of the UE. At time instance 1024, the discard timer may be started again.

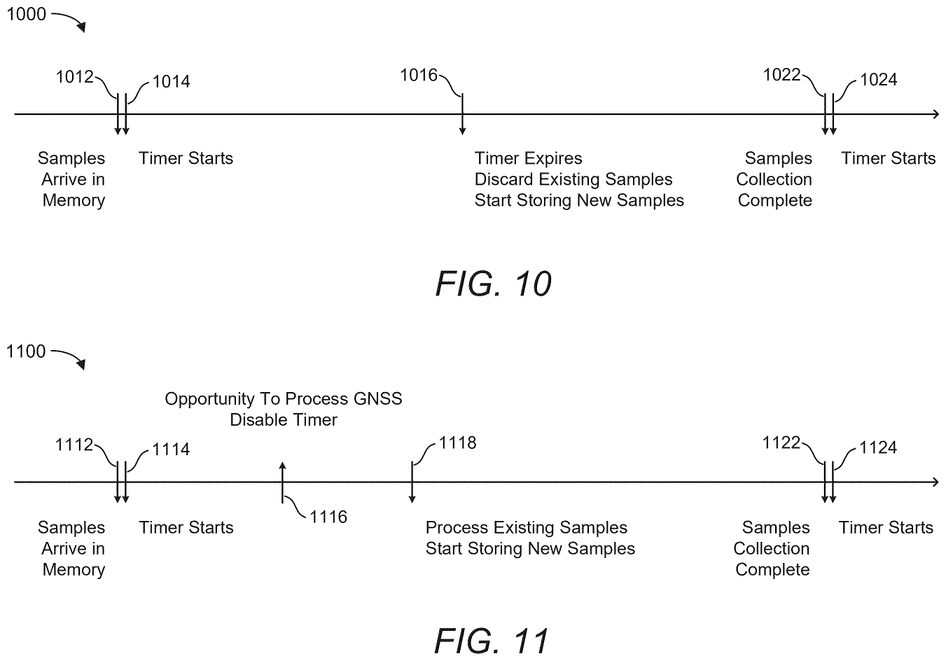

FIG. 11 illustrates a second timing diagram 1100 of an example positioning signal processing, according to aspects of the disclosure. The second timing diagram 1100 shows techniques for processing stored ADC samples corresponding to GNSS positioning signals that may be used to support time-sharing of a UE's hardware resources. The second timing diagram 1100 may be implemented in a UE or network device, such as the UE 104, 204, 304, 404, 504 or other UEs or network devices described herein.

In some examples, the stored ADC samples corresponding to GNSS positioning signals arrive in the one or more memories of the UE at time instance 1112 and a discard timer starts at time instance 1114. At time instance 1116, the UE may identify an opportunity to process stored ADC samples corresponding to GNSS positioning signals and disable the discard timer. The existing ADC samples corresponding to GNSS positioning signals may be processed at time instance 1118, and the UE may start the process of storing new ADC samples corresponding to GNSS positioning signals.

At time instance 1122, the collection of new ADC samples corresponding to GNSS positioning signals may be completed and stored in the one or more memories of the UE. At time instance 1124, the discard timer may be started again.

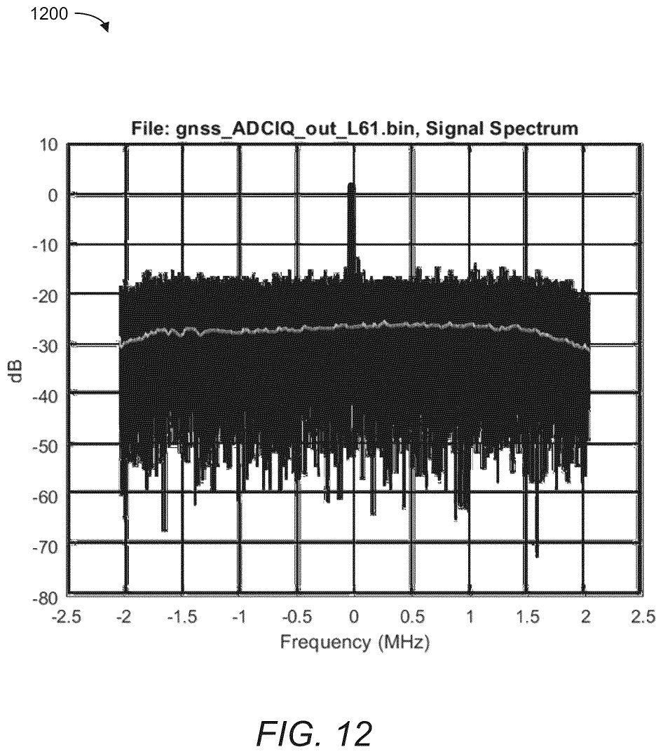

FIG. 12 illustrates an example simulation results signal spectrum plot 1200 corresponding to NTN communication and positioning frequency band reception and time-shared processing using common modem hardware resources, according to aspects of the disclosure. More specifically, the simulation results signal spectrum plot 1200 corresponds to a UE having a common RFFE and DFE design as shown and described in the example of FIG. 9.

The simulation results signal spectrum plot 1200 were produced using a GNSS signal configuration that includes a GPS L1CA space vehicle identification (SVID) of 1; a signal strength of 45 dBHz; and a center frequency of 1575.42 MHz. The GNSS signal configuration also includes an added Doppler frequency component of −3000 Hz. The radio frequency samples associated with the simulation results signal spectrum plot 1200 were generated first by normalizing the signal (e.g., thermal noise to standard deviation=1.0 (I_{RMS}=\sqrt{2}, Q_{RMS}=\sqrt{2})), and then scaling the signal by 0.003. Three scenarios were tested with successful simulation results: (1) GNSS signal transmission with no interference; (2) GNSS signal transmission with a carrier wave (CW) tone jammer at 1576 MHz; and (3) GNSS signal transmission with an LTE Band 14 2^{nd} harmonic jammer.

In the simulation results signal spectrum plot 1200, the common RFFE and DFE design as illustrated in the second block diagram 900 was used to process GNSS radio frequency signal samples and generate 2-bit complex IQ samples at 2.046 MHz. Additionally, the simulation results signal spectrum plot 1200 corresponds to the test scenario (3) GNSS signal transmission with an LTE Band 14 2^{nd} harmonic jammer.

FIG. 13 illustrates an example simulation results energy grid 1340 corresponding to NTN communication and positioning frequency band reception and time-shared processing using common modem hardware resources, according to aspects of the disclosure. More specifically, the simulation results energy grid 1340 corresponds to the simulation results signal spectrum plot 1200 of FIG. 12, in which the common RFFE and DFE design as illustrated in the second block diagram 900 was used to process GNSS radio frequency signal samples and generate 2-bit complex IQ samples at 2.046 MHz.

Additionally, like the simulation results signal spectrum plot 1200, the simulation results energy grid 1340 corresponds to the test scenario (3) GNSS signal transmission with an LTE Band 14 2^{nd} harmonic jammer a UE having a common RFFE and DFE design as shown and described in the example of FIG. 9. It is to be appreciated that the complex IQ samples in the simulation results signal spectrum plot 1200 were processed using software techniques to generate the cross-ambiguity function illustrated in the simulation results energy grid 1340 of FIG. 13.

A signal peak 1342 derived from the cross-ambiguity function of the simulation results energy grid 1340 is shown. Additionally, the measured results associated with the simulation results energy grid 1340 include a carrier-to-noise power density (C/No) of 44.88 dBHz as compared to the original signal strength of 45 dBHz. The measured results also include a measured Doppler frequency component of −3001.41 Hz as compared to the originally added Doppler frequency component of −3000 Hz.

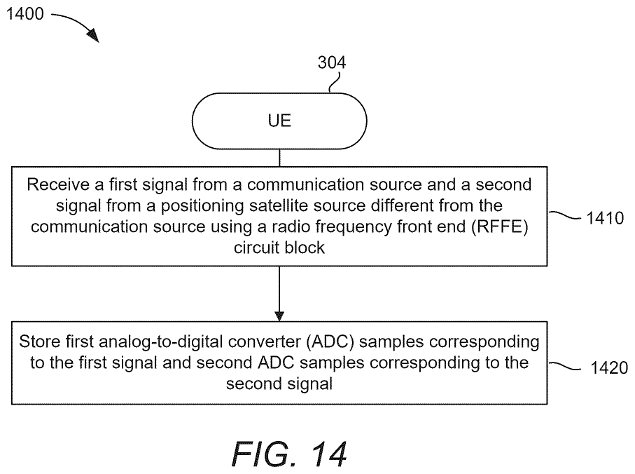

FIG. 14 is a flowchart of an example process 1400 associated with NTN communication and positioning frequency band reception, according to aspects of the disclosure. In some implementations, one or more process blocks of FIG. 14 may be performed by a user equipment (UE) (e.g., UE 104, 204, 304, 404, 504). In some implementations, one or more process blocks of FIG. 14 may be performed by another device or a group of devices separate from or including the UE. Additionally, or alternatively, one or more process blocks of FIG. 14 may be performed by one or more components of UE 304, such as processor(s) 342, memory 340, satellite signal receiver 330, and RFFE/DFE reception component(s) 348, any or all of which may be means for performing the operations of process 1400.

As shown in FIG. 14, process 1400 may include, at block 1410, receiving a first signal from a communication source and a second signal from a positioning satellite source different from the communication source using a radio frequency front end (RFFE) circuit block. Means for performing the operation of block 1410 may include the processor(s) 342, memory 340, satellite signal receiver 330, or RFFE/DFE reception component(s) 348 of the UE 304. For example, the UE 304 may receive a first signal from a communication source and a second signal from a positioning satellite source different from the communication source using a radio frequency front end (RFFE) circuit block (e.g., included in satellite signal receiver 330).

As further shown in FIG. 14, process 1400 may include, at block 1420, storing first analog-to-digital converter (ADC) samples corresponding to the first signal and second ADC samples corresponding to the second signal. Means for performing the operation of block 1420 may include the processor(s) 342, memory 340, satellite signal receiver 330, or RFFE/DFE reception component(s) 348 of the UE 304. For example, the UE 304 may store first analog-to-digital converter (ADC) samples corresponding to the first signal and second ADC samples corresponding to the second signal (e.g., using memory 340 and/or RFFE/DFE reception component(s) 348).

Process 1400 may include additional implementations, such as any single implementation or any combination of implementations described below and/or in connection with one or more other processes described elsewhere herein.

In some aspects, the RFFE circuit block comprises an RFFE circuit having a local oscillator (LO) configured to a radio frequency between a first frequency range associated with the first signal and a second frequency range associated with the second signal, and a wideband ADC circuit having a sampling clock configured to sample the first frequency range and the second frequency range.

In some aspects, process 1400 includes processing the stored first ADC samples using a first digital front end (DFE) circuit block, and processing the stored second ADC samples using a second DFE circuit block different from the first DFE circuit block.

In some aspects, process 1400 includes configuring one or more components of a digital front end (DFE) circuit block with a first software configuration for use during a first time period, processing the stored first ADC samples using the DFE circuit block during the first time period, configuring the one or more components of the DFE circuit block with a second software configuration different from the first software configuration for use during a second time period different from the first time period, and processing the stored second ADC samples using the DFE circuit block during the second time period.

In some aspects, process 1400 includes the RFFE circuit block is a circuit block that is common with the DFE circuit block, and an ADC sampling reference clock operates continuously during a time period when the second signal from the positioning satellite source is received until post-processing of the stored second ADC samples is completed.

In some aspects, process 1400 includes processing the stored second ADC samples using a digital front end (DFE) circuit block, performing a post-processing operation on the processed second ADC samples, wherein the post-processing operation includes a coherent integration process, a non-coherent integration process, or both, and determining a single shot position fix based on the performed post-processing operation.

In some aspects, the DFE circuit block includes an intermediate frequency (IF) down conversion circuit, a decimation circuit, or any combination thereof.

In some aspects, process 1400 includes scheduling the stored second ADC samples for processing using the DFE circuit block during a measurement gap, a connected mode discontinuous reception (DRX) off period, an idle mode DRX off period, or any combination thereof.

In some aspects, process 1400 includes starting a discard timer when the second ADC samples are stored in one or more memories, and discarding the stored second ADC samples based on an expiration of the discard timer occurring prior to processing the stored second ADC samples.

In some aspects, process 1400 includes receiving an updated navigation message, and discarding the stored second ADC samples based on receiving the updated navigation message.

In some aspects, process 1400 includes receiving an indication that a reception of the second signal from the positioning satellite source is scheduled for a first time period different from a second time period at which an uplink transmission is scheduled.

In some aspects, process 1400 includes the communication source corresponds to a non-terrestrial network (NTN) satellite, or the positioning satellite source corresponds to a global navigation satellite system (GNSS) satellite, or the first signal corresponds to an NTN n255 downlink frequency band, or the second signal corresponds to a GNSS L1 frequency band, or any combination thereof.

Although FIG. 14 shows example blocks of process 1400, in some implementations, process 1400 may include additional blocks, fewer blocks, different blocks, or differently arranged blocks than those depicted in FIG. 14. Additionally, or alternatively, two or more of the blocks of process 1400 may be performed in parallel.

As will be appreciated, a technical advantage of the process 1400 is enabling efficient GNSS-based positioning services in a low-cost UE, such as an IoT device by using at least some common modem hardware resources to receive communication signals and GNSS signals.

In the detailed description above it can be seen that different features are grouped together in examples. This manner of disclosure should not be understood as an intention that the example clauses have more features than are explicitly mentioned in each clause. Rather, the various aspects of the disclosure may include fewer than all features of an individual example clause disclosed. Therefore, the following clauses should hereby be deemed to be incorporated in the description, wherein each clause by itself can stand as a separate example. Although each dependent clause can refer in the clauses to a specific combination with one of the other clauses, the aspect(s) of that dependent clause are not limited to the specific combination. It will be appreciated that other example clauses can also include a combination of the dependent clause aspect(s) with the subject matter of any other dependent clause or independent clause or a combination of any feature with other dependent and independent clauses. The various aspects disclosed herein expressly include these combinations, unless it is explicitly expressed or can be readily inferred that a specific combination is not intended (e.g., contradictory aspects, such as defining an element as both an electrical insulator and an electrical conductor). Furthermore, it is also intended that aspects of a clause can be included in any other independent clause, even if the clause is not directly dependent on the independent clause.

Implementation examples are described in the following numbered clauses:

Clause 1. A method of wireless communication performed by a user equipment (UE), comprising: receiving a first signal from a communication source and a second signal from a positioning satellite source different from the communication source using a radio frequency front end (RFFE) circuit block; and storing first analog-to-digital converter (ADC) samples corresponding to the first signal and second ADC samples corresponding to the second signal.

Clause 2. The method of clause 1, wherein the RFFE circuit block comprises: an RFFE circuit having a local oscillator (LO) configured to a radio frequency between a first frequency range associated with the first signal and a second frequency range associated with the second signal; and a wideband ADC circuit having a sampling clock configured to sample the first frequency range and the second frequency range.

Clause 3. The method of any of clauses 1 to 2, further comprising: processing the stored first ADC samples using a first digital front end (DFE) circuit block; and processing the stored second ADC samples using a second DFE circuit block different from the first DFE circuit block.

Clause 4. The method of any of clauses 1 to 3, further comprising: configuring one or more components of a digital front end (DFE) circuit block with a first software configuration for use during a first time period; processing the stored first ADC samples using the DFE circuit block during the first time period; configuring the one or more components of the DFE circuit block with a second software configuration different from the first software configuration for use during a second time period different from the first time period; and processing the stored second ADC samples using the DFE circuit block during the second time period.

Clause 5. The method of clause 4, wherein: the RFFE circuit block is a circuit block that is common with the DFE circuit block, and an ADC sampling reference clock operates continuously during a time period when the second signal from the positioning satellite source is received until post-processing of the stored second ADC samples is completed.

Clause 6. The method of any of clauses 1 to 5, further comprising: processing the stored second ADC samples using a digital front end (DFE) circuit block; performing a post-processing operation on the processed second ADC samples, wherein the post-processing operation includes a coherent integration process, a non-coherent integration process, or both; and determining a single shot position fix based on the performed post-processing operation.

Clause 7. The method of clause 6, wherein the DFE circuit block includes: an intermediate frequency (IF) down conversion circuit, a decimation circuit; or any combination thereof.

Clause 8. The method of any of clauses 6 to 7, further comprising: scheduling the stored second ADC samples for processing using the DFE circuit block during a measurement gap, a connected mode discontinuous reception (DRX) off period, an idle mode DRX off period, or any combination thereof.

Clause 9. The method of any of clauses 1 to 8, further comprising: starting a discard timer when the second ADC samples are stored in one or more memories; and discarding the stored second ADC samples based on an expiration of the discard timer occurring prior to processing the stored second ADC samples.

Clause 10. The method of any of clauses 1 to 9, further comprising: receiving an updated navigation message; and discarding the stored second ADC samples based on receiving the updated navigation message.

Clause 11. The method of any of clauses 1 to 10, further comprising: receiving an indication that a reception of the second signal from the positioning satellite source is scheduled for a first time period different from a second time period at which an uplink transmission is scheduled.

Clause 12. The method of any of clauses 1 to 11, wherein: the communication source corresponds to a non-terrestrial network (NTN) satellite, the positioning satellite source corresponds to a global navigation satellite system (GNSS) satellite, the first signal corresponds to an NTN n255 downlink frequency band, the second signal corresponds to a GNSS L1 frequency band, or any combination thereof.

Clause 13. A user equipment (UE), comprising: one or more memories; one or more transceivers; and one or more processors communicatively coupled to the one or more memories and the one or more transceivers, the one or more processors, either alone or in combination, configured to: receive, via the one or more transceivers, a first signal from a communication source and a second signal from a positioning satellite source different from the communication source using a radio frequency front end (RFFE) circuit block; and store first analog-to-digital converter (ADC) samples corresponding to the first signal and second ADC samples corresponding to the second signal.

Clause 14. The UE of clause 13, wherein the RFFE circuit block comprises: an RFFE circuit having a local oscillator (LO) configured to a radio frequency between a first frequency range associated with the first signal and a second frequency range associated with the second signal; and a wideband ADC circuit having a sampling clock configured to sample the first frequency range and the second frequency range.

Clause 15. The UE of any of clauses 13 to 14, wherein the one or more processors, either alone or in combination, are further configured to: process the stored first ADC samples using a first digital front end (DFE) circuit block; and process the stored second ADC samples using a second DFE circuit block different from the first DFE circuit block.

Clause 16. The UE of any of clauses 13 to 15, wherein the one or more processors, either alone or in combination, are further configured to: configure one or more components of a digital front end (DFE) circuit block with a first software configuration for use during a first time period; process the stored first ADC samples using the DFE circuit block during the first time period; configure the one or more components of the DFE circuit block with a second software configuration different from the first software configuration for use during a second time period different from the first time period; and process the stored second ADC samples using the DFE circuit block during the second time period.

Clause 17. The UE of clause 16, wherein: the RFFE circuit block is a circuit block that is common with the DFE circuit block, and an ADC sampling reference clock operates continuously during a time period when the second signal from the positioning satellite source is received until post-processing of the stored second ADC samples is completed.

Clause 18. The UE of any of clauses 13 to 17, wherein the one or more processors, either alone or in combination, are further configured to: process the stored second ADC samples using a digital front end (DFE) circuit block; perform a post-processing operation on the processed second ADC samples, wherein the post-processing operation includes a coherent integration process, a non-coherent integration process, or both; and determine a single shot position fix based on the performed post-processing operation.

Clause 19. The UE of clause 18, wherein the DFE circuit block includes: an intermediate frequency (IF) down conversion circuit, a decimation circuit; or any combination thereof.

Clause 20. The UE of any of clauses 18 to 19, wherein the one or more processors, either alone or in combination, are further configured to: schedule the stored second ADC samples for processing using the DFE circuit block during a measurement gap, a connected mode discontinuous reception (DRX) off period, an idle mode DRX off period, or any combination thereof.

Clause 21. The UE of any of clauses 13 to 20, wherein the one or more processors, either alone or in combination, are further configured to: start a discard timer when the second ADC samples are stored in one or more memories; and discard the stored second ADC samples based on an expiration of the discard timer occurring prior to processing the stored second ADC samples.

Clause 22. The UE of any of clauses 13 to 21, wherein the one or more processors, either alone or in combination, are further configured to: receive, via the one or more transceivers, an updated navigation message; and discard the stored second ADC samples based on receiving the updated navigation message.

Clause 23. The UE of any of clauses 13 to 22, wherein the one or more processors, either alone or in combination, are further configured to: receive, via the one or more transceivers, an indication that a reception of the second signal from the positioning satellite source is scheduled for a first time period different from a second time period at which an uplink transmission is scheduled.

Clause 24. The UE of any of clauses 13 to 23, wherein: the communication source corresponds to a non-terrestrial network (NTN) satellite, the positioning satellite source corresponds to a global navigation satellite system (GNSS) satellite, the first signal corresponds to an NTN n255 downlink frequency band, the second signal corresponds to a GNSS L1 frequency band, or any combination thereof.

Clause 25. A user equipment (UE), comprising: means for receiving a first signal from a communication source and a second signal from a positioning satellite source different from the communication source using a radio frequency front end (RFFE) circuit block; and means for storing first analog-to-digital converter (ADC) samples corresponding to the first signal and second ADC samples corresponding to the second signal.

Clause 26. The UE of clause 25, wherein the RFFE circuit block comprises: an RFFE circuit having a local oscillator (LO) configured to a radio frequency between a first frequency range associated with the first signal and a second frequency range associated with the second signal; and a wideband ADC circuit having a sampling clock configured to sample the first frequency range and the second frequency range.

Clause 27. The UE of any of clauses 25 to 26, further comprising: means for processing the stored first ADC samples using a first digital front end (DFE) circuit block; and means for processing the stored second ADC samples using a second DFE circuit block different from the first DFE circuit block.

Clause 28. The UE of any of clauses 25 to 27, further comprising: means for configuring one or more components of a digital front end (DFE) circuit block with a first software configuration for use during a first time period; means for processing the stored first ADC samples using the DFE circuit block during the first time period; means for configuring the one or more components of the DFE circuit block with a second software configuration different from the first software configuration for use during a second time period different from the first time period; and means for processing the stored second ADC samples using the DFE circuit block during the second time period.

Clause 29. The UE of clause 28, wherein: the RFFE circuit block is a circuit block that is common with the DFE circuit block, and an ADC sampling reference clock operates continuously during a time period when the second signal from the positioning satellite source is received until post-processing of the stored second ADC samples is completed.

Clause 30. The UE of any of clauses 25 to 29, further comprising: means for processing the stored second ADC samples using a digital front end (DFE) circuit block; means for performing a post-processing operation on the processed second ADC samples, wherein the post-processing operation includes a coherent integration process, a non-coherent integration process, or both; and means for determining a single shot position fix based on the performed post-processing operation.

Clause 31. The UE of clause 30, wherein the DFE circuit block includes: an intermediate frequency (IF) down conversion circuit, a decimation circuit; or any combination thereof.

Clause 32. The UE of any of clauses 30 to 31, further comprising: means for scheduling the stored second ADC samples for processing using the DFE circuit block during a measurement gap, a connected mode discontinuous reception (DRX) off period, an idle mode DRX off period, or any combination thereof.

Clause 33. The UE of any of clauses 25 to 32, further comprising: means for starting a discard timer when the second ADC samples are stored in one or more memories; and means for discarding the stored second ADC samples based on an expiration of the discard timer occurring prior to processing the stored second ADC samples.

Clause 34. The UE of any of clauses 25 to 33, further comprising: means for receiving an updated navigation message; and means for discarding the stored second ADC samples based on receiving the updated navigation message.

Clause 35. The UE of any of clauses 25 to 34, further comprising: means for receiving an indication that a reception of the second signal from the positioning satellite source is scheduled for a first time period different from a second time period at which an uplink transmission is scheduled.

Clause 36. The UE of any of clauses 25 to 35, wherein: the communication source corresponds to a non-terrestrial network (NTN) satellite, the positioning satellite source corresponds to a global navigation satellite system (GNSS) satellite, the first signal corresponds to an NTN n255 downlink frequency band, the second signal corresponds to a GNSS L1 frequency band, or any combination thereof.

Clause 37. A non-transitory computer-readable medium storing computer-executable instructions that, when executed by a user equipment (UE), cause the UE to: receive a first signal from a communication source and a second signal from a positioning satellite source different from the communication source using a radio frequency front end (RFFE) circuit block; and store first analog-to-digital converter (ADC) samples corresponding to the first signal and second ADC samples corresponding to the second signal.

Clause 38. The non-transitory computer-readable medium of clause 37, wherein the RFFE circuit block comprises: an RFFE circuit having a local oscillator (LO) configured to a radio frequency between a first frequency range associated with the first signal and a second frequency range associated with the second signal; and a wideband ADC circuit having a sampling clock configured to sample the first frequency range and the second frequency range.

Clause 39. The non-transitory computer-readable medium of any of clauses 37 to 38, further comprising computer-executable instructions that, when executed by the UE, cause the UE to: process the stored first ADC samples using a first digital front end (DFE) circuit block; and process the stored second ADC samples using a second DFE circuit block different from the first DFE circuit block.

Clause 40. The non-transitory computer-readable medium of any of clauses 37 to 39, further comprising computer-executable instructions that, when executed by the UE, cause the UE to: configure one or more components of a digital front end (DFE) circuit block with a first software configuration for use during a first time period; process the stored first ADC samples using the DFE circuit block during the first time period; configure the one or more components of the DFE circuit block with a second software configuration different from the first software configuration for use during a second time period different from the first time period; and process the stored second ADC samples using the DFE circuit block during the second time period.

Clause 41. The non-transitory computer-readable medium of clause 40, wherein: the RFFE circuit block is a circuit block that is common with the DFE circuit block, and an ADC sampling reference clock operates continuously during a time period when the second signal from the positioning satellite source is received until post-processing of the stored second ADC samples is completed.

Clause 42. The non-transitory computer-readable medium of any of clauses 37 to 41, further comprising computer-executable instructions that, when executed by the UE, cause the UE to: process the stored second ADC samples using a digital front end (DFE) circuit block; perform a post-processing operation on the processed second ADC samples, wherein the post-processing operation includes a coherent integration process, a non-coherent integration process, or both; and determine a single shot position fix based on the performed post-processing operation.

Clause 43. The non-transitory computer-readable medium of clause 42, wherein the DFE circuit block includes: an intermediate frequency (IF) down conversion circuit, a decimation circuit; or any combination thereof.

Clause 44. The non-transitory computer-readable medium of any of clauses 42 to 43, further comprising computer-executable instructions that, when executed by the UE, cause the UE to: schedule the stored second ADC samples for processing using the DFE circuit block during a measurement gap, a connected mode discontinuous reception (DRX) off period, an idle mode DRX off period, or any combination thereof.

Clause 45. The non-transitory computer-readable medium of any of clauses 37 to 44, further comprising computer-executable instructions that, when executed by the UE, cause the UE to: start a discard timer when the second ADC samples are stored in one or more memories; and discard the stored second ADC samples based on an expiration of the discard timer occurring prior to processing the stored second ADC samples.

Clause 46. The non-transitory computer-readable medium of any of clauses 37 to 45, further comprising computer-executable instructions that, when executed by the UE, cause the UE to: receive an updated navigation message; and discard the stored second ADC samples based on receiving the updated navigation message.

Clause 47. The non-transitory computer-readable medium of any of clauses 37 to 46, further comprising computer-executable instructions that, when executed by the UE, cause the UE to: receive an indication that a reception of the second signal from the positioning satellite source is scheduled for a first time period different from a second time period at which an uplink transmission is scheduled.

Clause 48. The non-transitory computer-readable medium of any of clauses 37 to 47, wherein: the communication source corresponds to a non-terrestrial network (NTN) satellite, the positioning satellite source corresponds to a global navigation satellite system (GNSS) satellite, the first signal corresponds to an NTN n255 downlink frequency band, the second signal corresponds to a GNSS L1 frequency band, or any combination thereof.

Clause 49. An apparatus for wireless communication, comprising: a radio frequency front end (RFFE) circuit configured to receive a first signal and a second signal different from the first signal communication source, the RFFE circuit having a local oscillator (LO) configured to a radio frequency between a first frequency range associated with the first signal and a second frequency range associated with the second signal; a wideband analog-to-digital converter (ADC) circuit operably coupled to the RFFE circuit, the wideband ADC circuit having a sampling clock configured to sample the first frequency range and the second frequency range; and one or more memories configured to store first ADC samples corresponding to the first signal and second ADC samples corresponding to the second signal.

Clause 50. The apparatus of clause 49, further comprising: a first digital front end (DFE) circuit block operably coupled to the wideband ADC circuit and configured to process the stored first ADC samples; and a second DFE circuit block operably coupled to the wideband ADC circuit configured to process the stored first ADC samples.

Clause 51. The apparatus of any of clauses 49 to 50, further comprising: a digital front end (DFE) circuit block operably coupled to the wideband ADC circuit and configured to obtain a first software configuration for use during a first time period and a second software configuration for use during a second time period different from the first time period.

Clause 52. The apparatus of any of clauses 49 to 51, wherein the LO of the RFFE circuit is set to 1,567 MHz plus or minus 8 MHz.

Clause 53. The apparatus of any of clauses 49 to 52, wherein the sampling clock of the wideband ADC circuit is set to 115.2 MHz or greater.

Clause 54. The apparatus of any of clauses 49 to 53, wherein the apparatus is an integrated circuit component.

Those of skill in the art will appreciate that information and signals may be represented using any of a variety of different technologies and techniques. For example, data, instructions, commands, information, signals, bits, symbols, and chips that may be referenced throughout the above description may be represented by voltages, currents, electromagnetic waves, magnetic fields or particles, optical fields or particles, or any combination thereof.

Further, those of skill in the art will appreciate that the various illustrative logical blocks, modules, circuits, and algorithm steps described in connection with the aspects disclosed herein may be implemented as electronic hardware, computer software, or combinations of both. To clearly illustrate this interchangeability of hardware and software, various illustrative components, blocks, modules, circuits, and steps have been described above generally in terms of their functionality. Whether such functionality is implemented as hardware or software depends upon the particular application and design constraints imposed on the overall system. Skilled artisans may implement the described functionality in varying ways for each particular application, but such implementation decisions should not be interpreted as causing a departure from the scope of the present disclosure.

The various illustrative logical blocks, modules, and circuits described in connection with the aspects disclosed herein may be implemented or performed with a general purpose processor, a digital signal processor (DSP), an ASIC, a field-programable gate array (FPGA), or other programmable logic device, discrete gate or transistor logic, discrete hardware components, or any combination thereof designed to perform the functions described herein. A general-purpose processor may be a microprocessor, but in the alternative, the processor may be any conventional processor, controller, microcontroller, or state machine. A processor may also be implemented as a combination of computing devices, for example, a combination of a DSP and a microprocessor, a plurality of microprocessors, one or more microprocessors in conjunction with a DSP core, or any other such configuration.

The methods, sequences and/or algorithms described in connection with the aspects disclosed herein may be embodied directly in hardware, in a software module executed by a processor, or in a combination of the two. A software module may reside in random access memory (RAM), flash memory, read-only memory (ROM), erasable programmable ROM (EPROM), electrically erasable programmable ROM (EEPROM), registers, hard disk, a removable disk, a CD-ROM, or any other form of storage medium known in the art. An example storage medium is coupled to the processor such that the processor can read information from, and write information to, the storage medium. In the alternative, the storage medium may be integral to the processor. The processor and the storage medium may reside in an ASIC. The ASIC may reside in a user terminal (e.g., UE). In the alternative, the processor and the storage medium may reside as discrete components in a user terminal.

In one or more example aspects, the functions described may be implemented in hardware, software, firmware, or any combination thereof. If implemented in software, the functions may be stored on or transmitted over as one or more instructions or code on a computer-readable medium. Computer-readable media includes both computer storage media and communication media including any medium that facilitates transfer of a computer program from one place to another. A storage media may be any available media that can be accessed by a computer. By way of example, and not limitation, such computer-readable media can comprise RAM, ROM, EEPROM, CD-ROM or other optical disk storage, magnetic disk storage or other magnetic storage devices, or any other medium that can be used to carry or store desired program code in the form of instructions or data structures and that can be accessed by a computer. Also, any connection is properly termed a computer-readable medium. For example, if the software is transmitted from a website, server, or other remote source using a coaxial cable, fiber optic cable, twisted pair, digital subscriber line (DSL), or wireless technologies such as infrared, radio, and microwave, then the coaxial cable, fiber optic cable, twisted pair, DSL, or wireless technologies such as infrared, radio, and microwave are included in the definition of medium. Disk and disc, as used herein, includes compact disc (CD), laser disc, optical disc, digital versatile disc (DVD), floppy disk and Blu-ray disc where disks usually reproduce data magnetically, while discs reproduce data optically with lasers. Combinations of the above should also be included within the scope of computer-readable media.

While the foregoing disclosure shows illustrative aspects of the disclosure, it should be noted that various changes and modifications could be made herein without departing from the scope of the disclosure as defined by the appended claims. For example, the functions, steps and/or actions of the method claims in accordance with the aspects of the disclosure described herein need not be performed in any particular order. Further, no component, function, action, or instruction described or claimed herein should be construed as critical or essential unless explicitly described as such. Furthermore, as used herein, the terms “set,” “group,” and the like are intended to include one or more of the stated elements. Also, as used herein, the terms “has,” “have,” “having,” “comprises,” “comprising,” “includes,” “including,” and the like does not preclude the presence of one or more additional elements (e.g., an element “having” A may also have B). Further, the phrase “based on” is intended to mean “based, at least in part, on” unless explicitly stated otherwise. Also, as used herein, the term “or” is intended to be inclusive when used in a series and may be used interchangeably with “and/or,” unless explicitly stated otherwise (e.g., if used in combination with “either” or “only one of”) or the alternatives are mutually exclusive (e.g., “one or more” should not be interpreted as “one and more”). Furthermore, although components, functions, actions, and instructions may be described or claimed in the singular, the plural is contemplated unless limitation to the singular is explicitly stated. Accordingly, as used herein, the articles “a,” “an,” “the,” and “said” are intended to include one or more of the stated elements. Additionally, as used herein, the terms “at least one” and “one or more” encompass “one” component, function, action, or instruction performing or capable of performing a described or claimed functionality and also “two or more” components, functions, actions, or instructions performing or capable of performing a described or claimed functionality in combination.

What is claimed is:

1. A method of wireless communication performed by a user equipment (UE), comprising:
receiving a first signal from a communication source and a second signal from a positioning satellite source different from the communication source using a radio frequency front end (RFFE) circuit block; and
storing first analog-to-digital converter (ADC) samples corresponding to the first signal and second ADC samples corresponding to the second signal.

2. The method of claim 1, wherein the RFFE circuit block comprises:
an RFFE circuit having a local oscillator (LO) configured to a radio frequency between a first frequency range associated with the first signal and a second frequency range associated with the second signal; and
a wideband ADC circuit having a sampling clock configured to sample the first frequency range and the second frequency range.

3. The method of claim 1, further comprising:
processing the stored first ADC samples using a first digital front end (DFE) circuit block; and
processing the stored second ADC samples using a second DFE circuit block different from the first DFE circuit block.

4. The method of claim 1, further comprising:
configuring one or more components of a digital front end (DFE) circuit block with a first software configuration for use during a first time period;
processing the stored first ADC samples using the DFE circuit block during the first time period;
configuring the one or more components of the DFE circuit block with a second software configuration different from the first software configuration for use during a second time period different from the first time period; and
processing the stored second ADC samples using the DFE circuit block during the second time period.

5. The method of claim 4, wherein:
the RFFE circuit block is a circuit block that is common with the DFE circuit block, and
an ADC sampling reference clock operates continuously during a time period when the second signal from the positioning satellite source is received until post-processing of the stored second ADC samples is completed.

6. The method of claim 1, further comprising:
processing the stored second ADC samples using a digital front end (DFE) circuit block;
performing a post-processing operation on the processed second ADC samples, wherein the post-processing operation includes a coherent integration process, a non-coherent integration process, or both; and
determining a single shot position fix based on the performed post-processing operation.

7. A user equipment (UE), comprising:
one or more memories;
one or more transceivers; and
one or more processors communicatively coupled to the one or more memories and the one or more transceivers, the one or more processors, either alone or in combination, configured to:
receive, via the one or more transceivers, a first signal from a communication source and a second signal from a positioning satellite source different from the communication source using a radio frequency front end (RFFE) circuit block; and
store first analog-to-digital converter (ADC) samples corresponding to the first signal and second ADC samples corresponding to the second signal.

8. The UE of claim 7, wherein the RFFE circuit block comprises:
an RFFE circuit having a local oscillator (LO) configured to a radio frequency between a first frequency range associated with the first signal and a second frequency range associated with the second signal; and
a wideband ADC circuit having a sampling clock configured to sample the first frequency range and the second frequency range.

9. The UE of claim 7, wherein the one or more processors, either alone or in combination, are further configured to:
process the stored first ADC samples using a first digital front end (DFE) circuit block; and
process the stored second ADC samples using a second DFE circuit block different from the first DFE circuit block.

10. The UE of claim 7, wherein the one or more processors, either alone or in combination, are further configured to:
configure one or more components of a digital front end (DFE) circuit block with a first software configuration for use during a first time period;
process the stored first ADC samples using the DFE circuit block during the first time period;
configure the one or more components of the DFE circuit block with a second software configuration different from the first software configuration for use during a second time period different from the first time period; and
process the stored second ADC samples using the DFE circuit block during the second time period.

11. The UE of claim 10, wherein:
the RFFE circuit block is a circuit block that is common with the DFE circuit block, and
an ADC sampling reference clock operates continuously during a time period when the second signal from the positioning satellite source is received until post-processing of the stored second ADC samples is completed.

12. The UE of claim 7, wherein the one or more processors, either alone or in combination, are further configured to:
process the stored second ADC samples using a digital front end (DFE) circuit block;
perform a post-processing operation on the processed second ADC samples, wherein the post-processing operation includes a coherent integration process, a non-coherent integration process, or both; and
determine a single shot position fix based on the performed post-processing operation.

13. The UE of claim 12, wherein the DFE circuit block includes:
an intermediate frequency (IF) down conversion circuit,
a decimation circuit; or
any combination thereof.

14. The UE of claim 12, wherein the one or more processors, either alone or in combination, are further configured to:
schedule the stored second ADC samples for processing using the DFE circuit block during a measurement gap, a connected mode discontinuous reception (DRX) off period, an idle mode DRX off period, or any combination thereof.

15. The UE of claim 7, wherein the one or more processors, either alone or in combination, are further configured to:
start a discard timer when the second ADC samples are stored in one or more memories; and
discard the stored second ADC samples based on an expiration of the discard timer occurring prior to processing the stored second ADC samples.

16. The UE of claim 7, wherein the one or more processors, either alone or in combination, are further configured to:
receive, via the one or more transceivers, an updated navigation message; and
discard the stored second ADC samples based on receiving the updated navigation message.

17. The UE of claim 7, wherein the one or more processors, either alone or in combination, are further configured to:
receive, via the one or more transceivers, an indication that a reception of the second signal from the positioning satellite source is scheduled for a first time period different from a second time period at which an uplink transmission is scheduled.

18. The UE of claim 7, wherein:
the communication source corresponds to a non-terrestrial network (NTN) satellite,
the positioning satellite source corresponds to a global navigation satellite system (GNSS) satellite,
the first signal corresponds to an NTN n255 downlink frequency band,
the second signal corresponds to a GNSS L1 frequency band, or
any combination thereof.

19. A non-transitory computer-readable medium storing computer-executable instructions that, when executed by a user equipment (UE), cause the UE to:
receive a first signal from a communication source and a second signal from a positioning satellite source different from the communication source using a radio frequency front end (RFFE) circuit block; and
store first analog-to-digital converter (ADC) samples corresponding to the first signal and second ADC samples corresponding to the second signal.

20. The non-transitory computer-readable medium of claim 19, wherein the RFFE circuit block comprises:
an RFFE circuit having a local oscillator (LO) configured to a radio frequency between a first frequency range associated with the first signal and a second frequency range associated with the second signal; and
a wideband ADC circuit having a sampling clock configured to sample the first frequency range and the second frequency range.
